(19) United States
(12) Patent Application Publication
(10) Pub. No.: US 2025/0138416 A1
(43) Pub. Date: May 1, 2025

(54) RESIST COMPOSITIONS, METHODS FOR MANUFACTURING SEMICONDUCTOR DEVICES USING THE SAME AND MULTILAYERED STRUCTURES FORMED USING THE SAME

(71) Applicant: Samsung Electronics Co., Ltd., Suwon-si (KR)

(72) Inventors: JIN-KYUN LEE, Incheon (KR); SUNG IL LEE, Suwon-si (KR); KANGHO PARK, Suwon-si (KR); YEJIN KU, Incheon (KR); GAYOUNG KIM, Incheon (KR); CHOONGHAN RYU, Suwon-si (KR); CHANGYOUNG JEONG, Suwon-si (KR)

(73) Assignee: Inha University Research and Business Foundation, Incheon (KR)

(21) Appl. No.: 18/921,277

(22) Filed: Oct. 21, 2024

(30) Foreign Application Priority Data
Oct. 26, 2023 (KR) 10-2023-0144961
Apr. 16, 2024 (KR) 10-2024-0051002

(51) Int. Cl. G03F 7/004; G03F 7/20; G03F 7/32

(52) U.S. Cl. CPC G03F 7/0043; G03F 7/2004; G03F 7/32

(57) ABSTRACT

A resist composition includes an alkylated tin-oxo nanocluster and a compound having Lewis basicity. The alkylated tin-oxo nanocluster includes a core structure including tin oxide, and an alkyl group of 1 to 20 carbon atoms, combined with the tin element of the core structure. The compound includes a polymer or an organic single molecule, having a functional group that functions as a Lewis base, and the functional group is a functional group containing lone pair electrons.

### CROSS-REFERENCE TO RELATED APPLICATIONS

This U.S. non-provisional patent application claims priority under 35 U.S.C. § 119 of Korean Patent Application Nos. 10-2023-0144961, filed on Oct. 26, 2023, and 10-2024-0051002, filed on Apr. 16, 2024, the entire contents of which are hereby incorporated by reference.

### FIELD

The present disclosure herein relates to resist compositions for photolithography used for the manufacture of semiconductor devices, methods for manufacturing semiconductor devices using the same and multilayered structures formed using the same.

### BACKGROUND

Photolithography may include an exposing process and a developing process. The conductance of the exposing process may include exposing a resist layer to a specific wavelength of light to induce the change of the chemical structure of the resist layer. The conductance of the developing process may include the selective removing of the exposed part or the unexposed part of the resist layer by using a solubility difference between the exposed part and the unexposed part.

Recently, as semiconductor devices are highly integrated and downsized, the line width of patterns in semiconductor devices is miniaturized. In order to form minute patterns, various studies are being conducted to address the need improve the resolution and sensitivity of resist patterns formed by photolithography.

### SUMMARY

In an aspect, the present disclosure addresses the need in the art and provides a metal oxide-based positive tone resist composition which may be used for an extreme ultraviolet or e-beam lithography.

Another aspect of the present disclosure provides a method for manufacturing a semiconductor device using the resist composition, and a multilayer structure formed using the resist composition.

Aspects of the present disclosure are not limited to the aforementioned aspects, and unreferred other aspects may be clearly understood by a person skilled in the art from the description below.

In some embodiments, a resist composition according to the present disclosure may include an alkylated tin oxide nanocluster (hereinafter, an alkylated tin-oxo nanocluster) and a compound having Lewis basicity. The alkylated tin-oxo nanocluster may include a core structure including tin oxide, and an alkyl group of 1 to 20 carbon atoms, combined with the tin element of the core structure. The alkylated tin-oxo nanocluster may further include a counter anion ionic bonded with the core structure. The alkylated tin-oxo nanocluster may be represented by Formula 1.

[(R—Sn)₁₂O₁₄(OH)₆]²⁺[Rx⁻]₂ [Formula 1]

In Formula 1, R is an alkyl group of 1 to 20 carbon atoms, Rx⁻ is a counter anion and is a sulfonate anion or a carboxylate anion.

The compound may include a polymer or an organic single molecule, the compound having a functional group that functions as a Lewis base, and the functional group may be a functional group containing lone pair electrons.

A method for manufacturing a semiconductor device according to the present disclosure may include forming an etching target layer on a substrate, forming a photoresist layer on the etching target layer, performing an exposing process on the photoresist layer, and performing a developing process to selectively remove an exposed area of the photoresist layer. The photoresist layer may include an alkylated tin-oxo nanocluster and a compound having Lewis basicity. The alkylated tin-oxo nanocluster may include a core structure including tin oxide, and an alkyl group of 1 to 20 carbon atoms, combined with the tin element of the core structure. The alkylated tin-oxo nanocluster may further include a counter anion ionic bonded with the core structure. The alkylated tin-oxo nanocluster may be represented by Formula 1. The compound may include a polymer or an organic single molecule, having a functional group that functions as a Lewis base, and the functional group may be a functional group containing lone pair electrons.

A multilayer structure according to the present disclosure may include an etching target layer on a substrate, and a photoresist layer on the etching target layer. The photoresist layer may include an alkylated tin-oxo nanocluster and a compound having Lewis basicity. The alkylated tin-oxo nanocluster may include a core structure including tin oxide, and an alkyl group of 1 to 20 carbon atoms, combined with the tin element of the core structure. The alkylated tin-oxo nanocluster may further include a counter anion ionic bonded with the core structure. The alkylated tin-oxo nanocluster may be represented by Formula 1. The compound may include a polymer or an organic single molecule, the compound having a functional group that functions as a Lewis base, and the functional group may be a functional group containing lone pair electrons.

### BRIEF DESCRIPTION OF THE FIGURES

The accompanying drawings are included to provide a further understanding of the inventive concept, and are incorporated in and constitute a part of this specification. The drawings illustrate example embodiments of the inventive concept and, together with the description, serve to explain principles of the inventive concept. In the drawings:

FIG. 1A is a graph showing nuclear magnetic resonance spectrum results of tin-oxo nanocluster having dodecylbenzenesulfonate as a counter anion (DSBTOC) synthesized according to an exemplary embodiment described in Experimental Example 1, and FIG. 1B is a graph showing Fourier transform infrared spectrum (FTIR) results of DSBTOC synthesized according to an exemplary embodiment described in Experimental Example 1;

FIG. 2 is a graph showing exposure sensitivity of a resist thin film on an e-beam lithography process according to an exemplary embodiment described in Experimental Example 2;

FIG. 3 illustrates scanning electron microscopic images of positive tone resist patterns formed by an e-beam lithography process according to an exemplary embodiment described in Experimental Example 2;

FIG. 4 illustrates an image of an optical microscope and an image of a surface profiler for a resist thin film formed by an e-beam lithography process according to an exemplary embodiment described in Experimental Example 3;

FIG. 5 is a graph showing exposure sensitivity of a resist thin film on an e-beam lithography process according to an exemplary embodiment described in Experimental Example 3;

FIG. 6 illustrates scanning electron microscopic images of positive tone resist patterns formed by an e-beam lithography process according to an exemplary embodiment described in Experimental Example 3;

FIG. 7 is a graph showing exposure sensitivity of a resist thin film on an e-beam lithography process according to an exemplary embodiment described in Experimental Example 4;

FIG. 8 illustrates scanning electron microscopic images of positive tone resist patterns formed by an e-beam lithography process according to an exemplary embodiment described in Experimental Example 4;

FIG. 9 is a graph showing exposure sensitivity of a resist thin film on an e-beam lithography process according to an exemplary embodiment described in Experimental Example 5;

FIG. 10 illustrates scanning electron microscopic images of positive tone resist patterns formed by an e-beam lithography process according to an exemplary embodiment described in Experimental Example 5;

FIG. 11 illustrates scanning electron microscopic images of positive tone resist patterns formed by an e-beam lithography process according to an exemplary embodiment described in Experimental Example 6;

FIG. 12 is a diagram showing the ¹H-NMR spectrum of TA-A synthesized according to an exemplary embodiment described in Experimental Example 7;

FIG. 13 is a graph showing exposure sensitivity of a resist thin film on an e-beam lithography process according to an exemplary embodiment described in Experimental Example 8;

FIG. 14 illustrates scanning electron microscopic images of positive tone resist patterns formed by an e-beam lithography process according to an exemplary embodiment described in Experimental Example 8;

FIG. 15 illustrates scanning electron microscopic images of positive tone resist patterns formed by an extreme ultraviolet lithography process according to an exemplary embodiment described in Experimental Example 9;

FIG. 16 is a graph showing measurement results of solubility (dark loss) under non-exposure conditions for DSBTOC, a mixture of DSBTOC and a copolymer of 4-hydroxystyrene (HOST) and methyl methacrylate (MMA) (P(HOST-MMA)), and P(HOST-MMA) according to an exemplary embodiment described in Experimental Example 10;

FIG. 17 is a graph showing measurement results of solubility (dark loss) under non-exposure conditions for DSBTOC, a mixture of DSBTOC and, 4′,4″,4′″,4″″,4′″″-[[Ethane-1,1,1-triyltris(benzene-4,1-diyl)]tris(ethane-1,1,1-triyl)]hexaphenol (DHP), and DHP according to an exemplary embodiment described in Experimental Example 11; and

FIGS. 18 to 21 are cross-sectional views showing a method for manufacturing a semiconductor device using a resist composition according to an exemplary embodiment of the inventive concept.

### DETAILED DESCRIPTION

As used in the description, an alkyl group includes a linear, branched or cyclic monovalent saturated hydrocarbon group, unless otherwise indicated.

As used in the description, a hydrocarbon ring includes an aliphatic hydrocarbon ring and an aromatic hydrocarbon ring. The hydrocarbon ring may be a monocycle or a polycycle. The carbon number of the aromatic hydrocarbon ring is not specifically limited, but in some embodiments may be 5 to 30 carbons. In the description, the aromatic ring may include an aromatic hydrocarbon ring. A heterocycle includes an aliphatic heterocycle and an aromatic heterocycle. The heterocycle may be a monocycle or a polycycle.

As used in the description, “substituted or unsubstituted” may mean substituted or unsubstituted with at least one substituent selected from the group consisting of a hydrogen atom, a deuterium atom, a halogen atom, a hydroxyl group, an alkoxy group, an ether group, a halogenated alkyl group, a halogenated alkoxy group, a halogenated ether group, an alkyl group, an alkenyl group, an aryl group, a hydrocarbon ring group and a heterocyclic group. In addition, each of the illustrated substituents may be substituted or unsubstituted. For example, a halogenated alkoxy group may be referenced as an alkoxy group.

In the description, in the event a chemical bond is not shown at a position where a chemical bond is necessary, a hydrogen atom may be bonded, unless otherwise defined.

Hereinafter, embodiments of the inventive concept will be explained in detail with reference to attached drawings.

A resist composition according to embodiments of the inventive concept will be explained.

The resist composition according to embodiments of the inventive concept may be used for the manufacture of semiconductor devices and may be used in photolithography processes for the manufacture of a semiconductor device. The resist compositions may be used in, for example, an extreme ultraviolet or e-beam lithography process. Extreme ultraviolet may comprise ultraviolet having a wavelength of about 10 nm to about 124 nm, in particular, a wavelength of about 13.0 nm to about 13.9 nm, more particularly, a wavelength of about 13.4 nm to about 13.6 nm.

The resist composition may be a mixture composition including an alkylated tin-oxo nanocluster and a compound having Lewis basicity. The alkylated tin-oxo nanocluster may include a core structure including tin oxide, and an alkyl group of 1 to 20 carbon atoms, combined with the tin element of the core structure. The alkylated tin-oxo nanocluster may further include a counter anion ionic bonded with the core structure. The alkylated tin-oxo nanocluster may be represented by Formula 1.

[(R—Sn)₁₂O₁₄(OH)₆]²⁺[Rx⁻]₂ [Formula 1]

In Formula 1, R is an alkyl group of 1 to 20 carbon atoms, and Rx⁻ is a counter anion and is a sulfonate anion or a carboxylate anion.

Rx⁻ may be, for example, any one of a pentanoate anion, a pentenoate anion, a methacrylate anion, a benzoate anion, a p-toluate anion, an acetate anion, an isobutyrate anion, a malonate anion, a benzene sulfonate anion, a methane sulfonate anion, or a camphor-10-sulfonate anion.

Rx⁻ may be, for example, an alkyl benzene sulfonate anion and may have a structure according to Formula 2.

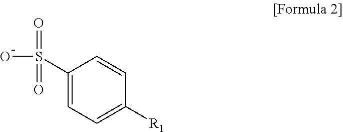

In Formula 2, R₁ is an alkyl group of 1 to 20 carbon atoms.

The tin-oxo nanocluster represented by Formula 1 may include a material represented by Formula 3.

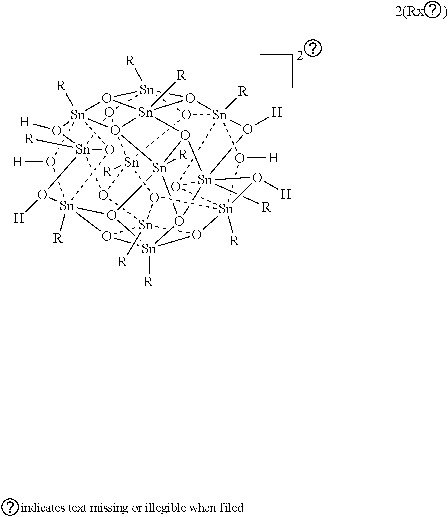

In Formula 3, R is a butyl group, and Rx⁻ is a counter anion represented by Formula 4.

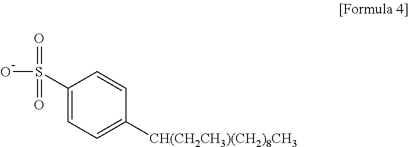

The compound having Lewis basicity may include a polymer or an organic single molecule, the compound having a functional group that functions as a Lewis base. The functional group that functions as a Lewis base may be a functional group having lone pair electrons such as a hydroxyl group, a phenol group, a thiol group, an amine group, a carboxylic acid group, an ester group, a carbonyl group, an amide group, a carbamate group, an urea group, a sulfoxy group, a sulfonyl group, a sulfone ester group, a cyanide group, or an isocyanide group.

The compound having Lewis basicity may include, for example, a polymer having a phenol group. The polymer may include a repeating unit represented by Formula 5.

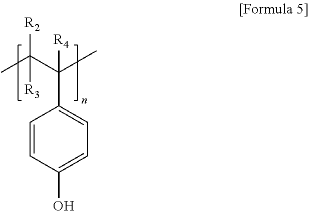

In Formula 5, R₂, R₃ and R₄ are each independently hydrogen, deuterium or an alkyl group of 1 to 10 carbon atoms, and “n” is an integer of 1 to 1000.

The polymer may include, for example, a copolymer represented by Formula 6.

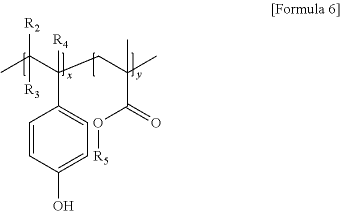

In Formula 6, R₂, R₃ and R₄ are each independently hydrogen, deuterium or an alkyl group of 1 to 10 carbon atoms, R₅ is hydrogen, deuterium, an alkyl group of 1 to 10 carbon atoms, or a substituted or unsubstituted hydrocarbon ring of 3 to 30 carbon atoms, “x” is an integer between 1 and 1000, and “y” is an integer between 1 and 1000.

The polymer may include, for example, a copolymer represented by Formula 6A.

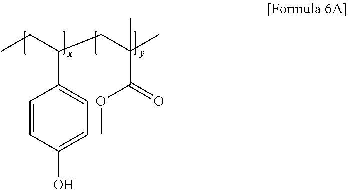

In Formula 6A, “x” is an integer between 1 and 1000, and “y” is an integer between 1 and 1000.

The compound having Lewis basicity may include, for example, an organic single molecule having a phenol group. The organic single molecule may be represented by Formula 7, Formula 8 or Formula 9.

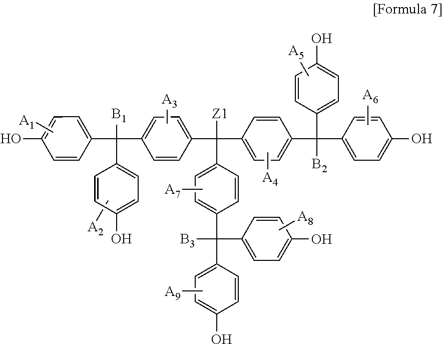

In Formula 7, A₁, A₂, A₃, A₄, A₅, A₆, A₇, A₈, and A₉ are each independently hydrogen, deuterium or an alkyl group of 1 to 10 carbon atoms, B₁, B₂, and B₃ are each independently hydrogen, deuterium or an alkyl group of 1 to 10 carbon atoms, and Z1 is hydrogen, deuterium, an alkyl group of 1 to 10 carbon atoms, or a substituted or unsubstituted hydrocarbon ring of 3 to 30 carbon atoms.

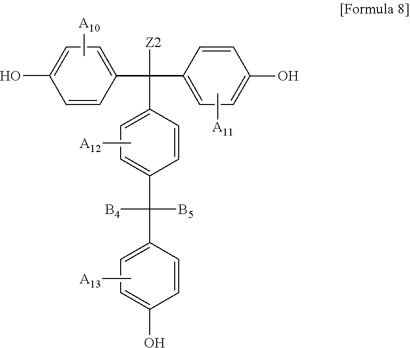

In Formula 8, A₁₀, A₁₁, A₁₂ and A₁₃ are each independently hydrogen, deuterium or an alkyl group of 1 to 10 carbon atoms, B₄ and B₅ are each independently hydrogen, deuterium or an alkyl group of 1 to 10 carbon atoms, and Z2 is hydrogen, deuterium, an alkyl group of 1 to 10 carbon atoms, or a substituted or unsubstituted hydrocarbon ring of 3 to 30 carbon atoms.

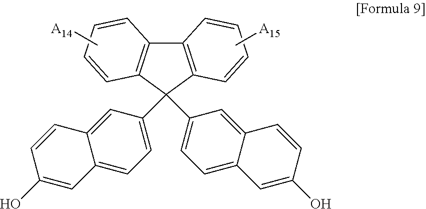

In Formula 9, A₁₄ and A₁₅ are each independently hydrogen, deuterium, an alkyl group of 1 to 10 carbon atoms, or a substituted or unsubstituted hydrocarbon ring of 3 to 30 carbon atoms.

The organic single molecule represented by Formula 7 may include a material represented by Formula 7A.

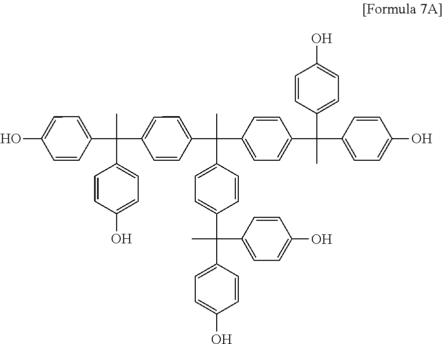 [SMILES: CC(c1ccc(O)cc1)(c1ccc(O)cc1)c1ccc(C(C)(c2ccc(C(C)(c3ccc(O)cc3)c3ccc(O)cc3)cc2)c2ccc(C(C)(c3ccc(O)cc3)c3ccc(O)cc3)cc2)cc1]

The organic single molecule represented by Formula 8 may include a material represented by Formula 8A.

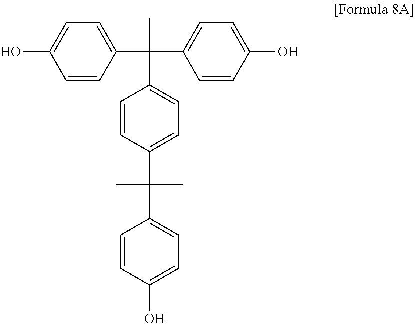 [SMILES: CC(C)(c1ccc(O)cc1)c1ccc(C(C)(c2ccc(O)cc2)c2ccc(O)cc2)cc1]

The organic single molecule represented by Formula 9 may include a material represented by Formula 9A.

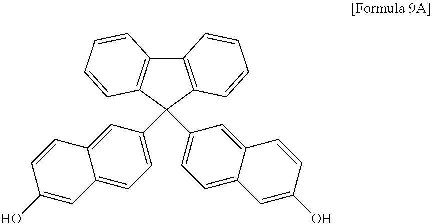 [SMILES: Oc1ccc2cc(C3(c4ccc5cc(O)ccc5c4)c4ccccc4-c4ccccc43)ccc2c1]

The compound having Lewis basicity may include, for example, an organic single molecule having an ester group. The organic single molecule may be a tannic acid-based compound and may be represented by Formula 10.

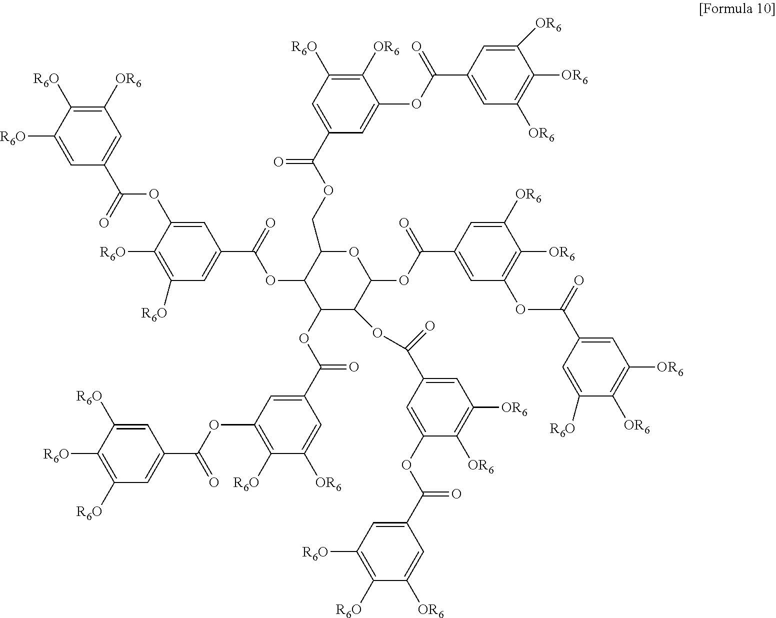

In Formula 10, R₆ may be represented by Formula 11.

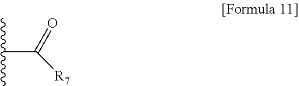

In Formula 11, R₇ is hydrogen, deuterium, an alkyl group of 1 to 10 carbon atoms, or a substituted or unsubstituted hydrocarbon ring of 3 to 30 carbon atoms.

The organic single molecule represented by Formula 10 may be a tannic acid-based acetate compound, and R₆ may be represented by Formula 11A.

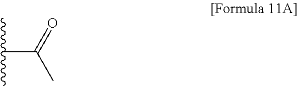 [SMILES: *C(C)=O]

In some embodiments, when the resist composition is irradiated with e-beam or extreme ultraviolet, an organic ligand (R) may be separated from the tin-oxo nanocluster represented by Formula 1 by e-beam or extreme ultraviolet photons, and accordingly, the tin-oxo nanocluster may have strong Lewis acidity. Accordingly, the solubility of the resist composition in a basic developing solution may increase. In some embodiments, the compound having Lewis basicity may have the functional group that functions as a Lewis base, and the functional group that functions as a Lewis base may be bonded to a tin atom that has lost the organic ligand (R) via acid-base interaction. Accordingly, the solubility of the resist composition in a basic developing solution may be controlled to a degree required, and the dissolution contrast between the exposed area and unexposed area of a photoresist layer formed by the resist composition may increase.

The resist composition may be a non-chemically amplified positive tone resist composition. Since the resist composition includes the tin-oxo nanocluster, the photoresist layer formed using the resist composition may have high resolution and sensitivity with respect to e-beam and extreme ultraviolet lithography processes. Further, since the resist composition includes the tin-oxo nanocluster, the etching resistance of the photoresist layer may increase. Since the resist composition further includes the compound having Lewis basicity, after being irradiated with e-beam or extreme ultraviolet, the resist composition may have a solubility degree required for a basic developing solution. Accordingly, the exposed area of the photoresist layer formed using the resist composition may be removed by the basic developing solution, and the dissolution contrast between the exposed area and unexposed area of the photoresist layer formed by the resist composition may increase.

### [Experimental Example 1] Synthesis of Tin-Oxo Nanocluster Having Dodecylbenzenesulfonate as Counter Anion (DSBTOC, Formula 3) (Reaction 1)

To a 50 cm³ vial, tetramethylammonium hydroxide pentahydrate (2.89 g, 16.0 mmol) and de-ionized water (DI water, 32 cm³) were added to prepare a solution, and butyltin trichloride (1.5 g, 5.3 mmol) was added to the solution to prepare a first reaction solution. The first reaction solution was vigorously stirred at room temperature for about 1 hour, and the reaction product was washed with DI water several times and filtered. The product thus obtained was dried in vacuum to obtain a tin-oxo nanocluster of a white solid form (BTOC, 1.0 g). The synthesized BTOC (1.0 g, 0.4 mmol) was dissolved in tetrahydrofuran (THF, 6 cm³), and an excessive amount of dodecylbenzenesulfonic acid was added thereto to prepare a second reaction solution. The second reaction solution was stirred at about 50° C. for about 20 minutes, and then concentrated under a reduced pressure. The concentrated material was precipitated in hexane (150 cm³), and the precipitate was filtered and dried to obtain DSBTOC as a white solid (0.5 g).

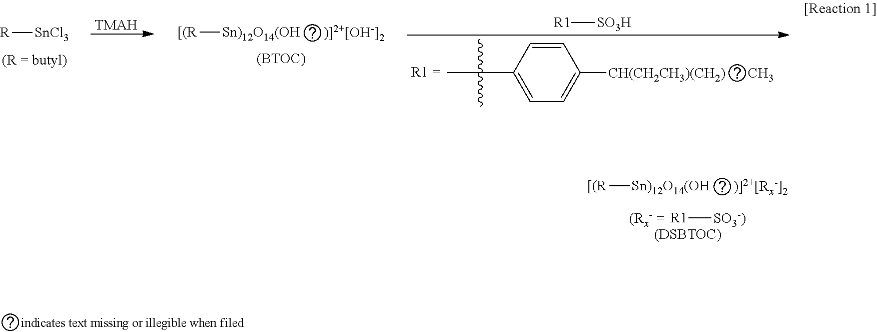

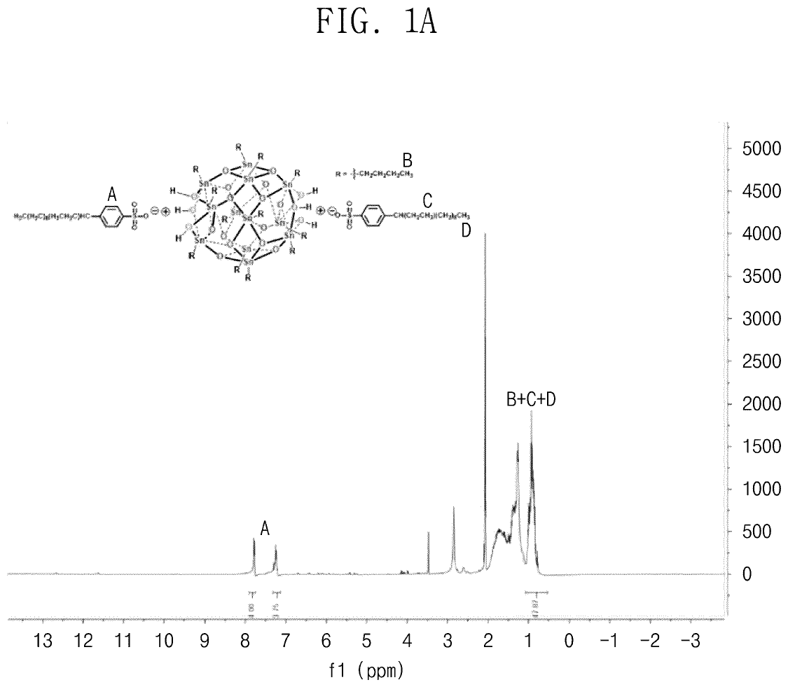

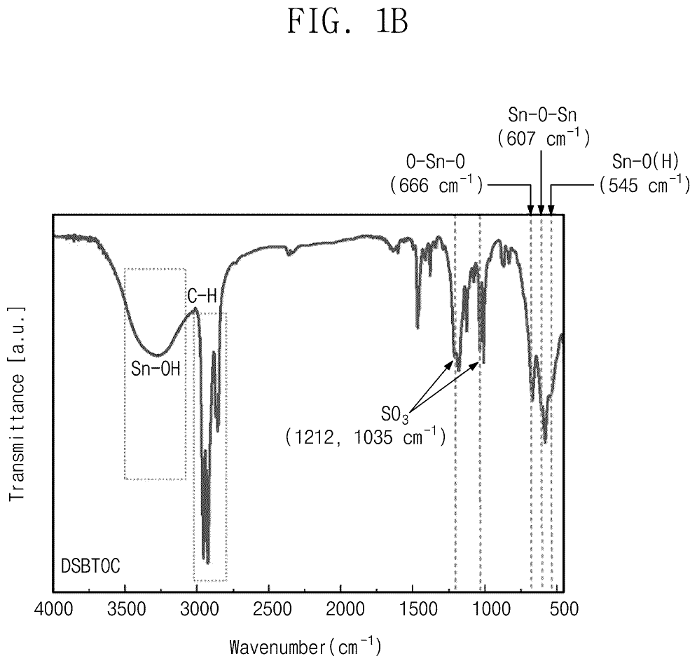

FIG. 1A is a graph showing nuclear magnetic resonance spectrum results of DSBTOC synthesized according to Experimental Example 1, and FIG. 1B is a graph showing Fourier transform infrared spectrum (FTIR) results of DSBTOC synthesized according to Experimental Example 1.

Referring to FIGS. 1A and 1B, it was confirmed that a tin-oxo nanocluster having dodecylbenzenesulfonate as a counter anion (DSBTOC) according to Experimental Example 1 was synthesized.

### [Experimental Example 2] E-Beam Lithography Evaluation on DSBTOC Resist Composition

DSBTOC was dissolved in a mixture solvent of n-butyl acetate (nBA) and methyl isobutyl ketone (MIBK) in a volume ratio of about 1:1 to prepare a resist composition solution into a concentration of about 2.7 wt/vol %. A solution in which hexamethyldisilazane (HMDS) was dissolved in propylene glycol monomethyl ether acetate (PGMEA) (about 20 wt %) was applied on a silicon substrate at about 3000 rpm for about 30 seconds by spin coating, and the substrate was heated at about 110° C. for about 1 minute. On the substrate treated with HMDS, the resist composition solution was applied at about 2000 rpm for about 60 seconds by spin coating and then, heated at about 80° C. for about 1 minute to form a resist thin film with a thickness of about 100 nm. The resist thin film was irradiated with e-beam of about 50 μC/cm² to about 1,500 μC/cm² under an acceleration voltage of about 80 keV. Then, a developing process was performed using a standard aqueous solution of about 2.38% tetramethylammonium hydroxide (TMAH) onto the resist thin film for about 60 seconds, and washing was performed with DI water for about 10 seconds to form a positive tone resist pattern.

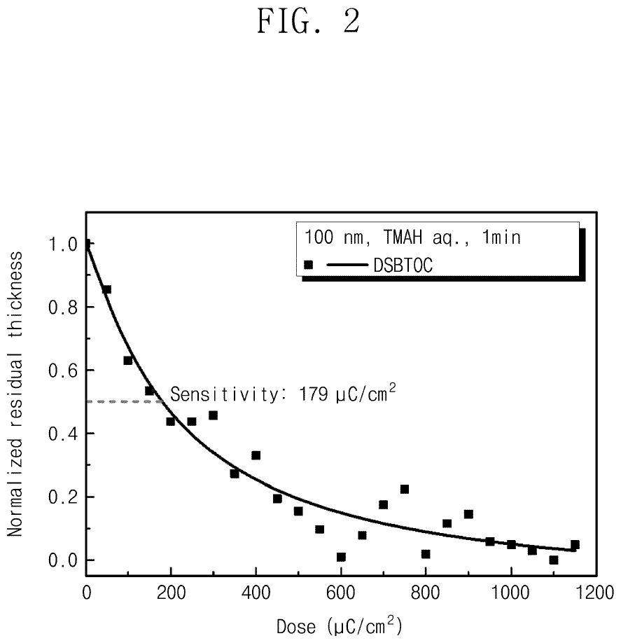

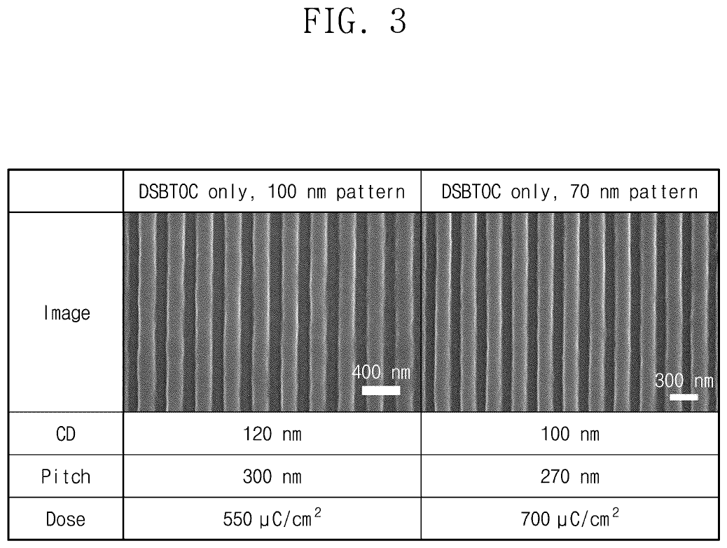

FIG. 2 is a graph showing exposure sensitivity of a resist thin film on an e-beam lithography process according to Experimental Example 2, and FIG. 3 illustrates scanning electron microscopic images of positive tone resist patterns formed by an e-beam lithography process according to Experimental Example 2.

Referring to FIG. 2, it was confirmed that about 50% of the thickness of the resist thin film was maintained in a case that e-beam of about 179 μC/cm² was irradiated onto the resist thin film (DSBTOC) with a thickness of about 100 nm, formed according to Experimental Example 2.

Referring to FIG. 3, e-beam of about 550 μC/cm² was irradiated onto the resist thin film (DSBTOC) formed according to Experimental Example 2 for patterning a resist pattern with a line width (critical dimension: CD) of about 100 nm, and a developing process was performed using a basic developing solution (TMAH). As a result, a positive tone resist pattern with a line width (CD) of about 120 nm was formed. E-beam of about 700 μC/cm² was irradiated onto the resist thin film (DSBTOC) formed according to Experimental Example 2 for patterning a resist pattern with a line width (CD) of about 70 nm, and a developing process was performed using a basic developing solution (TMAH). As a result, a positive tone resist pattern with a line width (CD) of about 100 nm was formed.

Referring to FIGS. 2 and 3, it was confirmed that a positive tone resist pattern was formed using the DSBTOC resist composition. Particularly, as e-beam is irradiated onto the resist thin film formed using the DSBTOC resist composition, the organic ligand (butyl group) of the tin-oxo nanocluster (DSBTOC) in the exposed area of the resist thin film may be separated, and accordingly, the tin-oxo nanocluster (DSBTOC) may have strong Lewis acidity. Then, during the developing process using the basic developing solution (TMAH), a hydroxyl group (—OH) that is a Lewis base of the basic developing solution (TMAH) may be bonded to a tin atom that has lost the organic ligand (butyl group), and accordingly, the solubility of the exposed area of the resist thin film with respect to the basic developing solution (TMAH) may increase. Accordingly, the exposed area of the resist thin film may be selectively removed by the developing process using the basic developing solution (TMAH), and accordingly, a positive tone resist pattern may be formed.

### [Experimental Example 3] E-Beam Lithography Evaluation on Mixture Resist Composition of DSBOTC and a Copolymer of 4-Hydroxystyrene (HOST) and Methyl Methacrylate (MMA) (P(HOST-MMA)) (Formula 6A)

DSBTOC and a P(HOST-MMA) copolymer were dissolved in a mixture solvent of n-butyl acetate (nBA) and PGMEA in a volume ratio of about 1:4 to prepare a resist composition solution into a concentration of about 3.0 wt/vol %. The P(HOST-MMA) is a copolymer of 4-hydroxystyrene (HOST) and methyl methacrylate (MMA), the composition ratio of HOST and MMA was about 55:45, and a number average molecular weight (Mn) was about 22 k (purchased from Kyung In Yang Haeng Co., Ltd.). The weight ratio of DSBTOC and P(HOST-MMA) in the resist composition was changed to about 1:0.5, about 1:0.25 and about 1:0.1.

A solution in which hexamethyldisilazane (HMDS) was dissolved in PGMEA (about 20 wt %) was applied on a silicon substrate at about 3000 rpm for about 30 seconds by spin coating, and the substrate was heated at about 110° C. for about 1 minute. On the substrate treated with HMDS, the resist composition solution was applied at about 2000 rpm for about 60 seconds by spin coating and heated at about 80° C. for about 1 minute to form a resist thin film with a thickness of about 90 nm. The resist thin film was irradiated with e-beam of about 50 μC/cm² to about 1,500 μC/cm² under an acceleration voltage of about 80 keV. Then, a developing process was performed on the resist thin film using a mixture solution of a standard aqueous solution of about 2.38% TMAH and DI water (the volume ratio of the standard aqueous solution of about 2.38% TMAH and DI water was changed to about 3:1, about 4:1 and about 10:1) for about 60 seconds, and washing was performed using DI water for about 10 seconds to form a positive tone resist pattern.

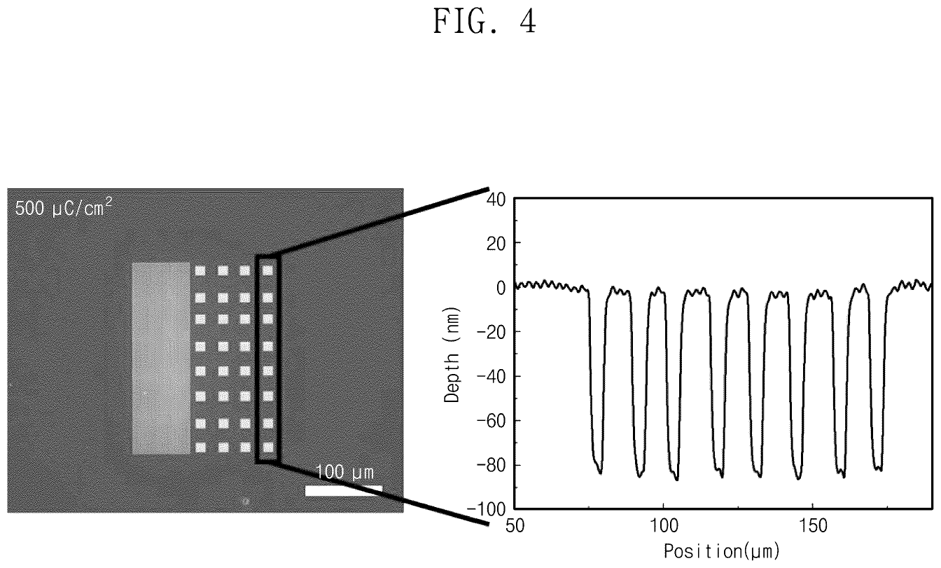

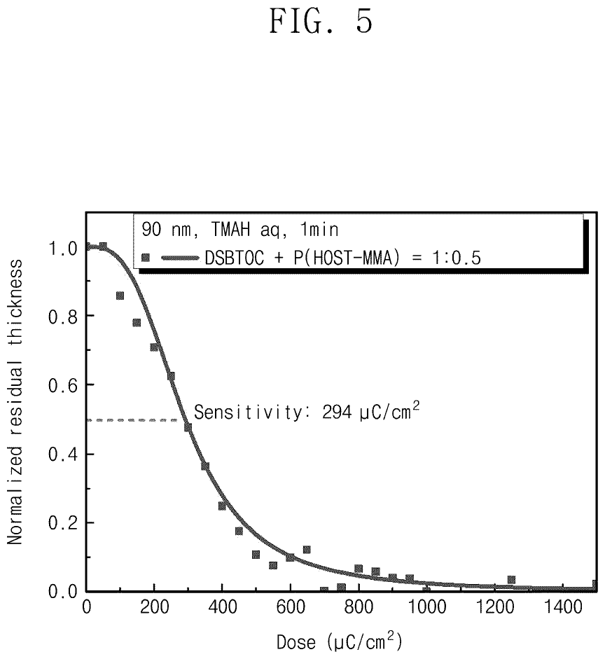

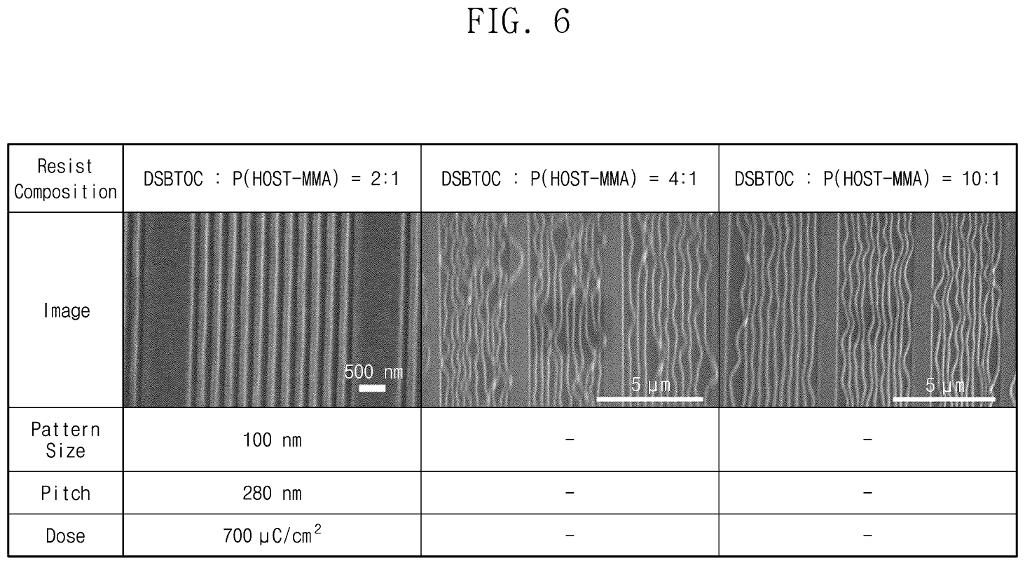

FIG. 4 illustrates an image of an optical microscope and an image of a surface profiler for a resist thin film formed by an e-beam lithography process according to Experimental Example 3, FIG. 5 is a graph showing exposure sensitivity of a resist thin film on an e-beam lithography process according to Experimental Example 3, and FIG. 6 illustrates scanning electron microscopic images of positive tone resist patterns formed by an e-beam lithography process according to Experimental Example 3.

Referring to FIG. 4, the thickness of the resist thin film (resist thin film of a mixture of DSBOTC and P(HOST-MMA)) formed according to Experimental Example 3 was measured using a surface profiler, and it was confirmed that the resist thin film (thin film of a mixture of DSBOTC and P(HOST-MMA)) was formed to a thickness of about 90 nm.

Referring to FIG. 5, it was confirmed that when the e-beam of about 294 μC/cm² was irradiated onto the resist thin film (weight ratio of DSBTOC and P(HOST-MMA)=about 1:0.5) with a thickness of about 90 nm, formed according to Experimental Example 3, about 50% of the thickness of the resist thin film was maintained. Further, it was confirmed that when the dosage of the e-beam was small, the solubility of the resist thin film with respect to the basic developing solution (TMAH) did not increase, and when the dosage of the e-beam increased above a certain amount, the solubility of the resist film in the basic developing solution (TMAH) increased.

Referring to FIG. 6, e-beam of about 700 μC/cm² was irradiated onto the resist thin film (weight ratio of DSBTOC and P(HOST-MMA)=about 1:0.5) formed according to Experimental Example 3 for patterning a resist pattern with a line width (CD) of about 100 nm, and a developing process was performed using a basic developing solution (TMAH). As a result, a positive tone resist pattern with a line width (CD) of about 100 nm was formed. In the cases of the resist thin films (weight ratios of DSBTOC and P(HOST-MMA)=about 1:0.25, about 1:0.1) formed according to Experimental Example 3, the resist thin films were damaged during the developing process.

Referring to FIGS. 4 to 6, it is confirmed that a positive tone resist pattern may be formed using the mixture resist composition of DSBTOC and P(HOST-MMA). Particularly, according to the irradiation of the e-beam onto the resist thin film formed using the mixture resist composition of DSBTOC and P(HOST-MMA), the organic ligand (butyl group) of the tin-oxo nanocluster (DSBTOC) may be separated in the exposed area of the resist thin film, and accordingly, the tin-oxo nanocluster (DSBTOC) may have strong Lewis acidity. In the exposed area of the resist thin film, a phenol group that is the Lewis base of the P(HOST-MMA) copolymer may be bonded to a tin atom that has lost the organic ligand (butyl group). Accordingly, the solubility of the exposed area with respect to a basic developing solution (TMAH) may be controlled, and the dissolution contrast between the exposed area and unexposed area of the resist thin film may increase. Then, the exposed area of the resist thin film may be selectively removed by the developing process using the basic developing solution (TMAH), and accordingly, a positive tone resist pattern may be formed.

### [Experimental Example 4] E-Beam Lithography Evaluation on Mixture Resist Composition of DSBTOC and, 4′,4″,4′″,4″″,4′″″-[[Ethane-1,1,1-triyltris(benzene-4,1-diyl)]tris(ethane-1,1,1-triyl)]hexaphenol (DHP) (Formula 7A)

DSBTOC and 4,4′,4″,4′″,4″″,4′″″-[[Ethane-1,1,1-triyltris(benzene-4,1-diyl)]tris(ethane-1,1,1-triyl)]hexaphenol (DHP, purchased from Accela Chembio Inc., USA) were dissolved in a mixture solvent of n-butyl acetate (nBA) and methyl isobutyl ketone (MIBK) in a volume ratio of about 1:1 to prepare a resist composition solution into a concentration of about 2.5 wt/vol %. The weight ratio of DSBTOC and DHP in the resist composition solution was changed to about 1:0.1 and about 1:0.25.

A solution in which HMDS was dissolved in PGMEA (about 20 wt %) was applied on a silicon substrate at about 3000 rpm for about 30 seconds by spin coating, and the substrate was heated at about 110° C. for about 1 minute. On the substrate treated with HMDS, the resist composition solution was applied at about 3000 rpm for about 60 seconds by spin coating and heated at about 80° C. for about 1 minute to form a resist thin film with a thickness of about 80 nm. The resist thin film was irradiated with e-beam of about 50 μC/cm² to about 1,500 μC/cm² under an acceleration voltage of about 80 keV. Then, a developing process was performed on the resist thin film using a mixture solution of a standard aqueous solution of about 2.38% TMAH and DI water (the volume ratio of the standard aqueous solution of about 2.38% TMAH and DI water was about 30:1) for about 60 seconds, and washing was performed using DI water for about 10 seconds to form a positive tone resist pattern.

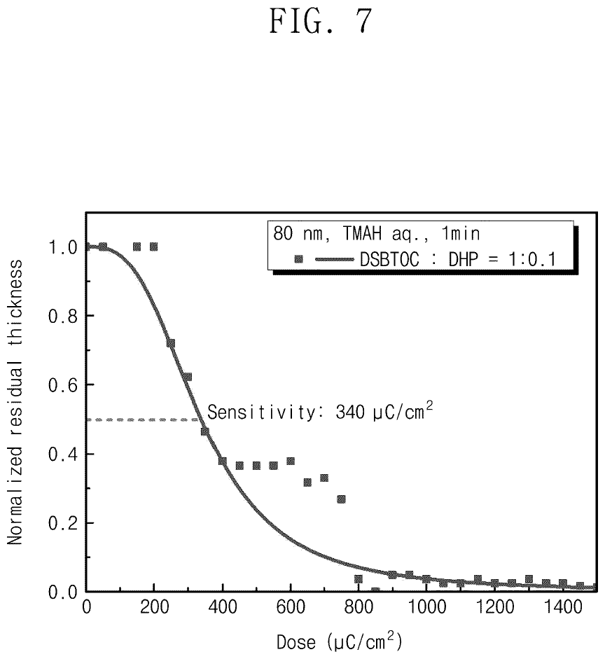

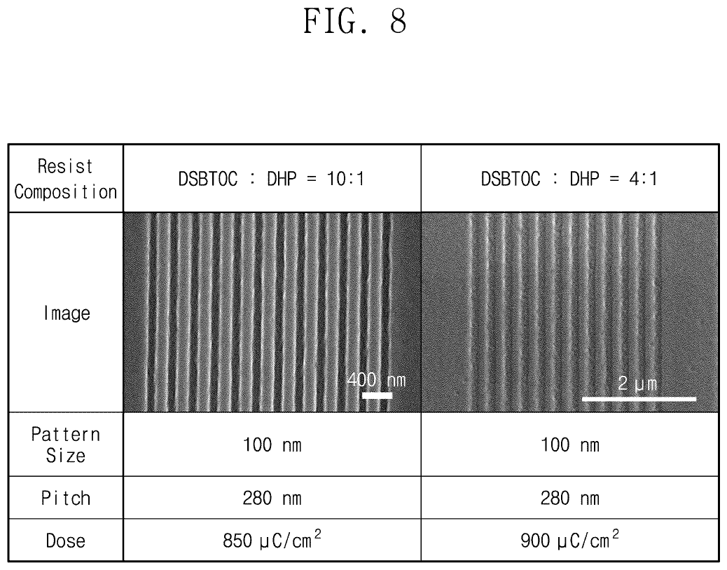

FIG. 7 is a graph showing exposure sensitivity of a resist thin film on an e-beam lithography process according to Experimental Example 4, and FIG. 8 illustrates scanning electron microscopic images of positive tone resist patterns formed by an e-beam lithography process according to Experimental Example 4.

Referring to FIG. 7, it was confirmed that when e-beam of about 340 μC/cm² was irradiated onto the resist thin film (weight ratio of DSBTOC and DHP=about 1:0.1) with a thickness of about 80 nm, formed according to Experimental Example 4, about 50% of the thickness of the resist thin film was maintained. Further, it was confirmed that when the dosage of the e-beam was small, the solubility of the resist thin film with respect to the basic developing solution (TMAH) did not increase, and when the dosage of the e-beam increased above a certain amount, the solubility of the resist film in the basic developing solution (TMAH) increased.

Referring to FIG. 8, e-beam of about 850 μC/cm² was irradiated onto the resist thin film (weight ratio of DSBTOC and DHP=about 1:0.1) formed according to Experimental Example 4 for patterning a resist pattern with a line width (CD) of about 100 nm, and a developing process was performed using a basic developing solution (TMAH). As a result, a positive tone resist pattern with a line width (CD) of about 100 nm was formed. E-beam of about 900 μC/cm² was irradiated onto the resist thin film (weight ratio of DSBTOC and DHP=about 1:0.25) formed according to Experimental Example 4 for patterning a resist pattern with a line width (CD) of about 100 nm, and a developing process was performed using a basic developing solution (TMAH). As a result, a positive tone resist pattern with a line width (CD) of about 100 nm was formed.

Referring to FIGS. 7 and 8, it is confirmed that a positive tone resist pattern may be formed using the mixture resist composition of DSBTOC and DHP. Particularly, according to the irradiation of the e-beam onto the resist thin film formed using the mixture resist composition of DSBTOC and DHP, the organic ligand (butyl group) of the tin-oxo nanocluster (DSBTOC) in the exposed area of the resist thin film may be separated, and accordingly, the tin-oxo nanocluster (DSBTOC) may have strong Lewis acidity. In the exposed area of the resist thin film, a phenol group that is the Lewis base of DHP single molecule may be bonded to a tin atom that has lost the organic ligand (butyl group). Accordingly, the solubility of the exposed area of the resist thin film with respect to the basic developing solution (TMAH) may be controlled, and the dissolution contrast between the exposed area and unexposed area of the resist thin film may increase. Then, the exposed area of the resist thin film may be selectively removed by the developing process using the basic developing solution (TMAH), and accordingly, a positive tone resist pattern may be formed.

### [Experimental Example 5] E-Beam Lithography Evaluation on Mixture Resist Composition of DSBTOC and T-Shape (Formula 8A)

DSBTOC and α,α,α′-tris(4-hydroxyphenyl)-1-ethyl-4-isopropylbenzene (T-shape, purchased from TCI Chemicals) were dissolved in a mixture solvent of n-butyl acetate (nBA) and methyl isobutyl ketone (MIBK) in a volume ratio of about 1:1 to prepare a resist composition solution into a concentration of about 2.5 wt/vol %. The weight ratio of DSBTOC and T-shape in the resist composition solution was changed to about 1:0.05, about 1:0.1, and about 1:0.2.

A solution in which HMDS was dissolved in PGMEA (about 20 wt %) was applied on a silicon substrate at about 3000 rpm for about 30 seconds by spin coating, and the substrate was heated at about 110° C. for about 1 minute. On the substrate treated with HMDS, the resist composition solution was applied at about 2000 rpm for about 60 seconds by spin coating and heated at about 80° C. for about 1 minute to form a resist thin film with a thickness of about 80 nm. The resist thin film was irradiated with e-beam of about 50 μC/cm² to about 1,500 μC/cm² under an acceleration voltage of about 80 keV. Then, a developing process was performed on the resist thin film using a mixture solution of a standard aqueous solution of about 2.38% TMAH and DI water (the volume ratio of the standard aqueous solution of about 2.38% TMAH and DI water was about 30:1) for about 60 seconds, and washing was performed using DI water for about 10 seconds to form a positive tone resist pattern.

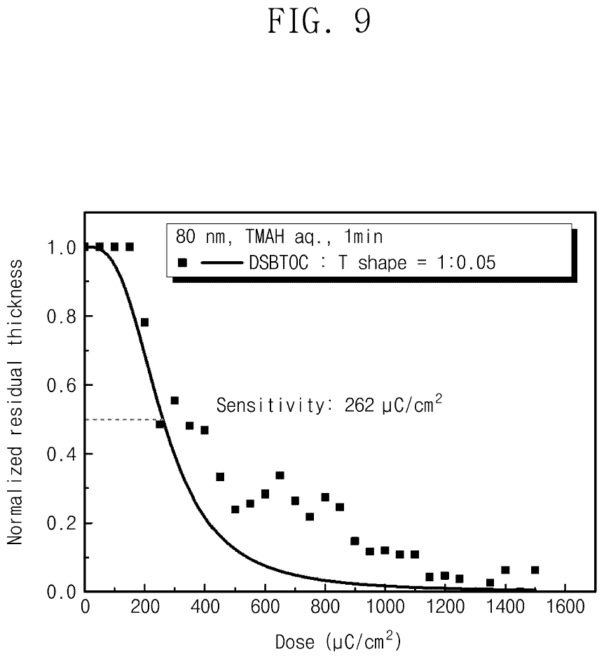

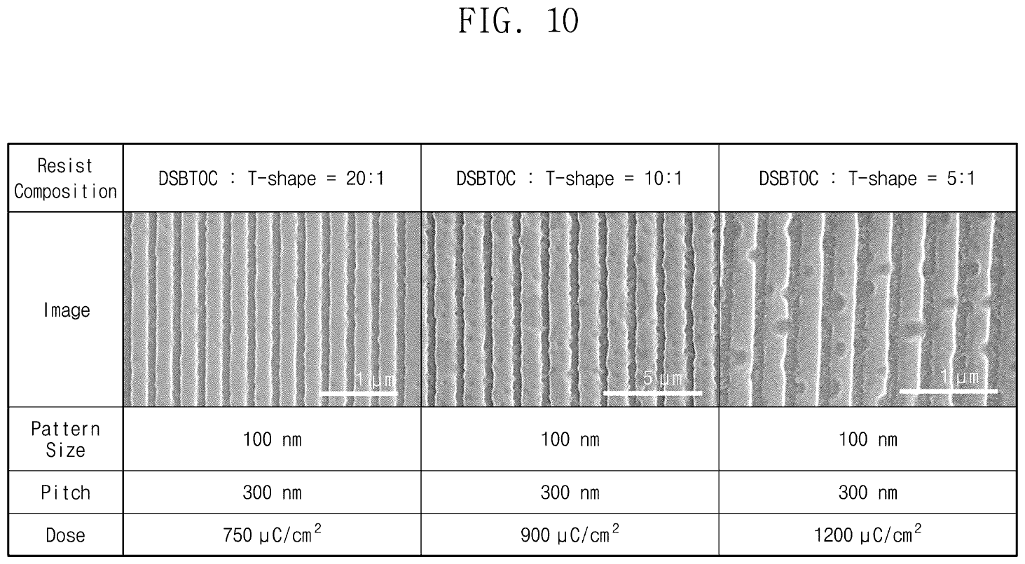

FIG. 9 is a graph showing exposure sensitivity of a resist thin film on an e-beam lithography process according to Experimental Example 5, and FIG. 10 illustrates scanning electron microscopic images of positive tone resist patterns formed by an e-beam lithography process according to Experimental Example 5.

Referring to FIG. 9, it was confirmed that when e-beam of about 262 μC/cm² was irradiated onto the resist thin film (weight ratio of DSBTOC and T-shape=about 1:0.05) with a thickness of about 80 nm, formed according to Experimental Example 5, about 50% of the thickness of the resist thin film was maintained. Further, it was confirmed that when the dosage of the e-beam was small, the solubility of the resist thin film with respect to the basic developing solution (TMAH) did not increase, and when the dosage of the e-beam increased above a certain amount, the solubility of the resist film in the basic developing solution (TMAH) increased.

Referring to FIG. 10, e-beam of about 750 μC/cm² was irradiated onto the resist thin film (weight ratio of DSBTOC and T-shape=about 1:0.05) formed according to Experimental Example 5 for patterning a resist pattern with a line width (CD) of about 100 nm, and a developing process was performed using a basic developing solution (TMAH). As a result, a positive tone resist pattern with a line width (CD) of about 100 nm was formed. E-beam of about 900 μC/cm² was irradiated onto the resist thin film (weight ratio of DSBTOC and T-shape=about 1:0.1) formed according to Experimental Example 5 for patterning a resist pattern with a line width (CD) of about 100 nm, and a developing process was performed using a basic developing solution (TMAH). As a result, a positive tone resist pattern with a line width (CD) of about 100 nm was formed. E-beam of about 1200 μC/cm² was irradiated onto the resist thin film (weight ratio of DSBTOC and T-shape=about 1:0.2) formed according to Experimental Example 5 for patterning a resist pattern with a line width (CD) of about 100 nm, and a developing process was performed using a basic developing solution (TMAH). As a result, a positive tone resist pattern with a line width (CD) of about 100 nm was formed.

Referring to FIGS. 9 and 10, it is confirmed that a positive tone resist pattern may be formed using the mixture resist composition of DSBTOC and T-shape. Particularly, according to the irradiation of the e-beam onto the resist thin film formed using the mixture resist composition of DSBTOC and T-shape, the organic ligand (butyl group) of the tin-oxo nanocluster (DSBTOC) in the exposed area of the resist thin film may be separated, and accordingly, the tin-oxo nanocluster (DSBTOC) may have strong Lewis acidity. In the exposed area of the resist thin film, a phenol group that is the Lewis base of a T-shape single molecule may be bonded to a tin atom that has lost the organic ligand (butyl group). Accordingly, the solubility of the exposed area of the resist thin film with respect to the basic developing solution (TMAH) may be controlled, and the dissolution contrast between the exposed area and unexposed area of the resist thin film may increase. Then, the exposed area of the resist thin film may be selectively removed by the developing process using the basic developing solution (TMAH), and accordingly, a positive tone resist pattern may be formed.

### [Experimental Example 6] E-Beam Lithography Evaluation on Mixture Resist Composition of DSBTOC and HNF (Formula 9A)

DSBTOC and 6,6′-(9H-Fluoren-9-ylidene)bis[2-naphthalenol] (HNF, purchased from U-CHEM) were dissolved in 2-methyltetrahydrofuran (2-MeTHF) to prepare a resist composition solution into a concentration of about 2.5 wt/vol %. The weight ratio of DSBTOC and HNF in the resist composition solution was changed to about 1:0.05 and about 1:0.1.

A solution in which HMDS was dissolved in PGMEA (about 20 wt %) was applied on a silicon substrate at about 3000 rpm for about 30 seconds by spin coating, and the substrate was heated at about 110° C. for about 1 minute. On the substrate treated with HMDS, the resist composition solution was applied at about 2000 rpm for about 60 seconds by spin coating and heated at about 80° C. for about 1 minute to form a resist thin film with a thickness of about 90 nm. The resist thin film was irradiated with e-beam of about 50 μC/cm² to about 1,500 μC/cm² under an acceleration voltage of about 80 keV. Then, a developing process was performed on the resist thin film using a standard aqueous solution of about 2.38% TMAH for about 60 seconds, and washing was performed using DI water for about 10 seconds to form a positive tone resist pattern.

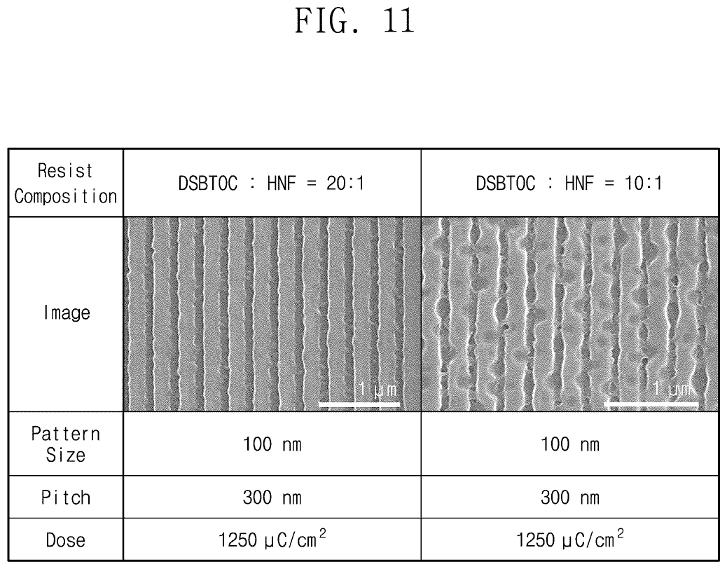

FIG. 11 illustrates scanning electron microscopic images of positive tone resist patterns formed by an e-beam lithography process according to Experimental Example 6.

Referring to FIG. 11, e-beam of about 1250 μC/cm² was irradiated onto the resist thin film (weight ratio of DSBTOC and HNF=about 1:0.05) formed according to Experimental Example 6 for patterning a resist pattern with a line width (CD) of about 100 nm, and a developing process was performed using a basic developing solution (TMAH). As a result, a positive tone resist pattern with a line width (CD) of about 100 nm was formed. E-beam of about 1250 μC/cm² was irradiated onto the resist thin film (weight ratio of DSBTOC and HNF=about 1:0.1) formed according to Experimental Example 6 for patterning a resist pattern with a line width (CD) of about 100 nm, and a developing process was performed using a basic developing solution (TMAH). As a result, a positive tone resist pattern with a line width (CD) of about 100 nm was formed.

It is confirmed that a positive tone resist pattern may be formed using the mixture resist composition of DSBTOC and HNF. Particularly, according to the irradiation of the e-beam onto the resist thin film formed using the mixture resist composition of DSBTOC and HNF, the organic ligand (butyl group) of the tin-oxo nanocluster (DSBTOC) in the exposed area of the resist thin film may be separated, and accordingly, the tin-oxo nanocluster (DSBTOC) may have strong Lewis acidity. In the exposed area of the resist thin film, a phenol group that is the Lewis base of a HNF single molecule may be bonded to a tin atom that has lost the organic ligand (butyl group). Accordingly, the solubility of the exposed area of the resist thin film with respect to the basic developing solution (TMAH) may be controlled, and the dissolution contrast between the exposed area and unexposed area of the resist thin film may increase. Then, the exposed area of the resist thin film may be selectively removed by the developing process using the basic developing solution (TMAH), and accordingly, a positive tone resist pattern may be formed.

### [Experimental Example 7] Synthesis of TA-A (Formula 10, Formula 11A, Reaction 2)

To a 25 cm³ seal tube, tannic acid (0.5 g, 0.29 mmol) and acetic anhydride (0.9 g, 8.82 mmol) were added and stirred at a temperature of about 120° C. for about 6 hours using pyridine (5 cm³) as a solvent. After finishing the reaction, the reaction solution was quenched using a 2 M HCl aqueous solution (8 cm³) and diluted in ethyl acetate (EtOAc). Then, an organic solvent layer was washed with water twice and then washed with a saturated sodium chloride (NaCl) aqueous solution (100 cm³) once more. Then, water contained in the organic solvent layer was removed using anhydrous MgSO₄, and the resultant was concentrated under reduced pressure conditions. The product thus formed was diluted in ethyl acetate and re-precipitated in hexane to obtain TA-A in a white powder form (tannic acid-based acetate compound, 0.46 g, 57%).

¹H NMR (400 MHz, (CD₃)₂SO): δ=7.89-7.35 (m, Ar—H), 2.40-2.10 (m, CH₃).

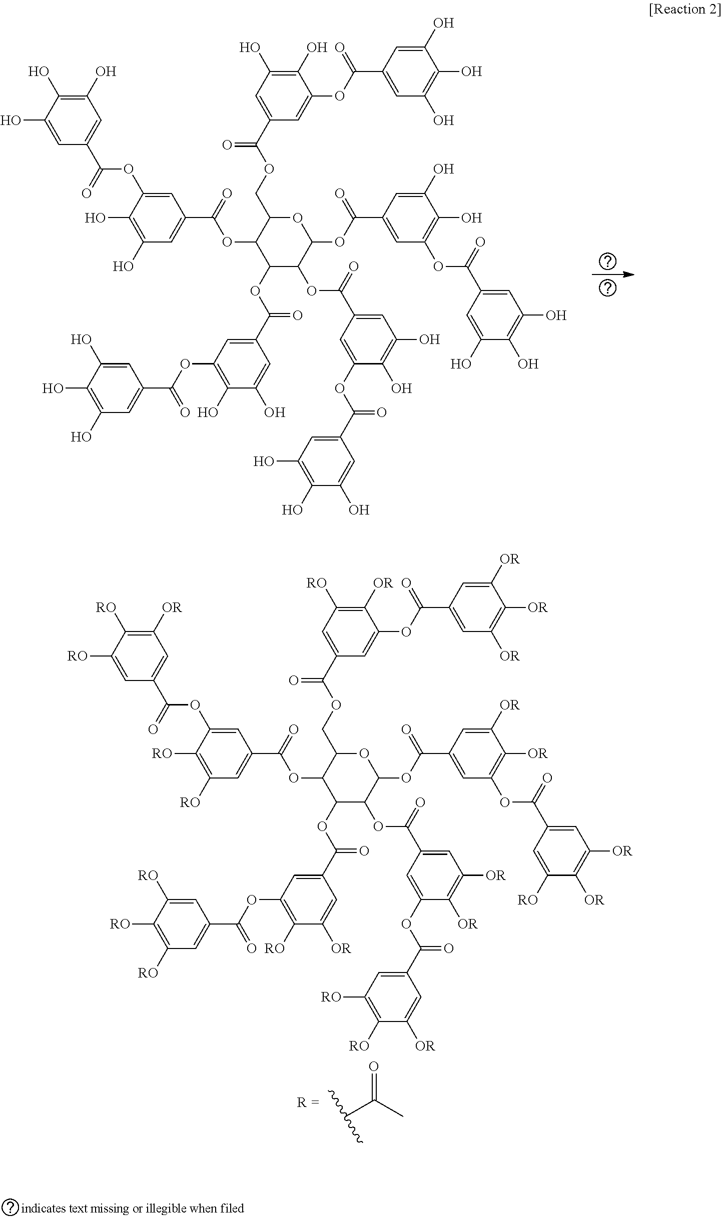

FIG. 12 is a diagram showing the ¹H-NMR spectrum of TA-A synthesized according to Experimental Example 7.

Referring to FIG. 12, it is confirmed that TA-A that is a tannic acid-based acetate compound was formed according to Experimental Example 7.

### [Experimental Example 8] E-Beam Lithography Evaluation on Mixture Resist Composition of DSBTOC and TA-A

DSBTOC and TA-A were dissolved in a mixture solvent of n-butyl acetate (nBA) and methyl isobutyl ketone (MIBK) in a volume ratio of about 1:1 to prepare a resist composition solution into a concentration of about 2.5 wt/vol %. The weight ratio of DSBTOC and TA-A in the resist composition solution was changed to about 1:0.1 and about 1:0.33.

A solution in which HMDS was dissolved in PGMEA (about 20 wt %) was applied on a silicon substrate at about 3000 rpm for about 30 seconds by spin coating, and the substrate was heated at about 110° C. for about 1 minute. On the substrate treated with HMDS, the resist composition solution was applied at about 2000 rpm for about 60 seconds by spin coating and heated at about 80° C. for about 1 minute to form a resist thin film with a thickness of about 90 nm. The resist thin film was irradiated with e-beam of about 50 μC/cm² to about 1,500 μC/cm² under an acceleration voltage of about 80 keV. A developing process was performed on the resist thin film using a mixture solution of a standard aqueous solution of about 2.38% TMAH and DI water (the volume ratio of the standard aqueous solution of about 2.38% TMAH and DI water was about 1:50) for about 60 seconds, and washing was performed using DI water for about 10 seconds to form a positive tone resist pattern.

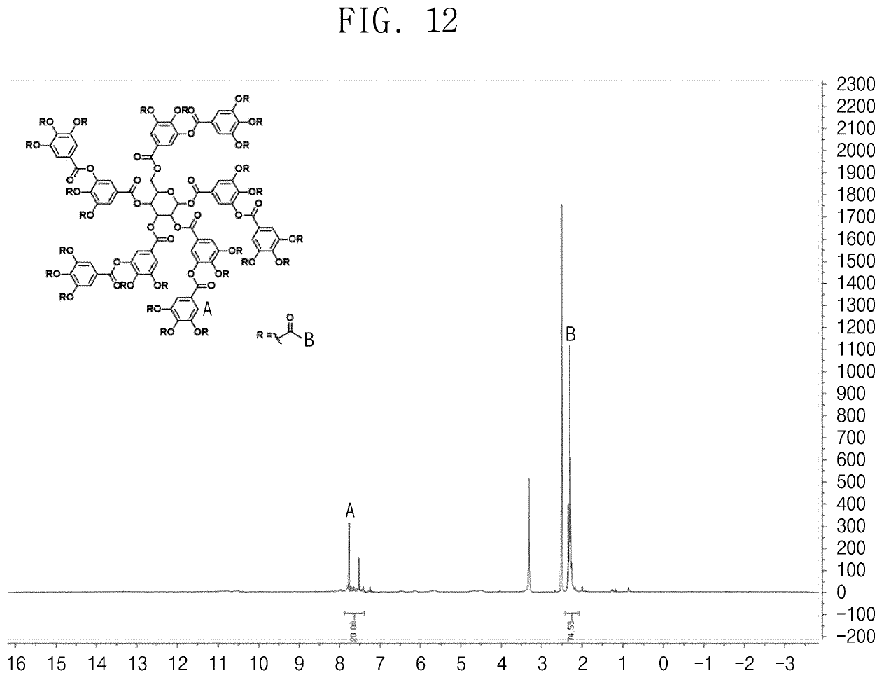

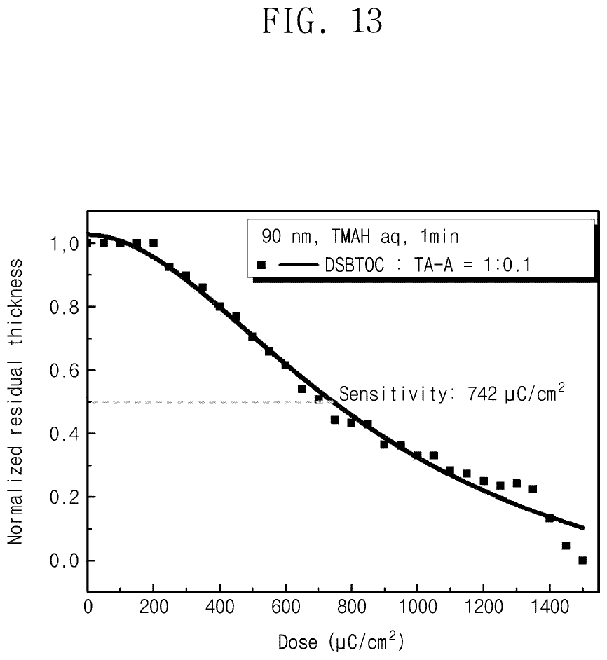

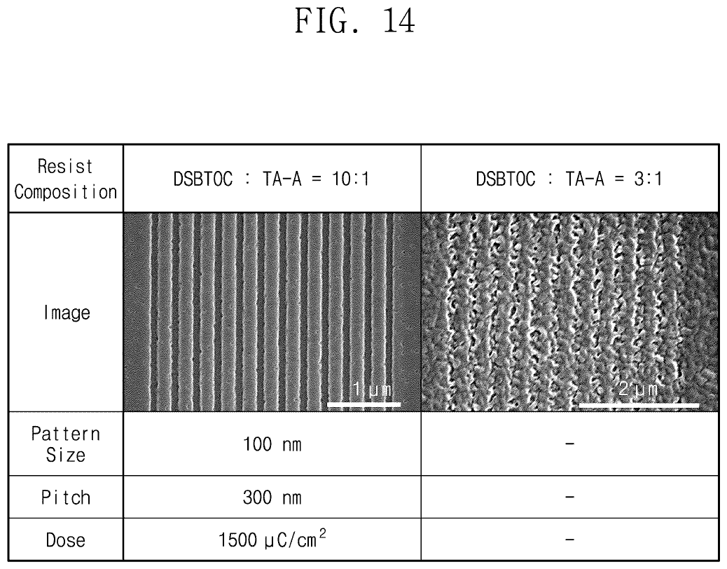

FIG. 13 is a graph showing exposure sensitivity of a resist thin film on an e-beam lithography process according to Experimental Example 8, and FIG. 14 illustrates scanning electron microscopic images of positive tone resist patterns formed by an e-beam lithography process according to Experimental Example 8.

Referring to FIG. 13, it was confirmed that when e-beam of about 742 μC/cm² was irradiated on the resist thin film (weight ratio of DSBTOC and TA-A=about 1:0.1) formed according to Experimental Example 8, about 50% of the thickness of the resist thin film was maintained. Further, it was confirmed that when the dosage of the e-beam was small, the solubility of the resist thin film with respect to the basic developing solution (TMAH) did not increase, and when the dosage of the e-beam increased above a certain amount, the solubility of the resist film in the basic developing solution (TMAH) increased.

Referring to FIG. 14, e-beam of about 1500 μC/cm² was irradiated onto the resist thin film (weight ratio of DSBTOC and TA-A=about 1:0.1) formed according to Experimental Example 8 for patterning a resist pattern with a line width (CD) of about 100 nm, and a developing process was performed using a basic developing solution (TMAH). As a result, a positive tone resist pattern with a line width (CD) of about 100 nm was formed. In the case of the resist thin film (weight ratio of DSBTOC and TA-A=about 1:0.33) formed according to Experimental Example 8, the resist thin film was damaged during the developing process.

Referring to FIGS. 13 and 14, it is confirmed that a positive tone resist pattern may be formed using the mixture resist composition of DSBTOC and TA-A. Particularly, according to the irradiation of the e-beam onto the resist thin film formed using the mixture resist composition of DSBTOC and TA-A, the organic ligand (butyl group) of the tin-oxo nanocluster (DSBTOC) in the exposed area of the resist thin film may be separated, and accordingly, the tin-oxo nanocluster (DSBTOC) may have strong Lewis acidity. In the exposed area of the resist thin film, an ester group that is the Lewis base of a TA-A single molecule may be bonded to a tin atom that has lost the organic ligand (butyl group). Accordingly, the solubility of the exposed area of the resist thin film with respect to the basic developing solution (TMAH) may be controlled, and the dissolution contrast between the exposed area and unexposed area of the resist thin film may increase. Then, the exposed area of the resist thin film may be selectively removed by the developing process using the basic developing solution (TMAH), and accordingly, a positive tone resist pattern may be formed.

### [Experimental Example 9] Extreme Ultraviolet Lithography Evaluation on Mixture Resist Composition of DSBTOC and DHP (Formula 7A)

DSBTOC and 4,4′,4″,4′″,4″″,4′″″-[[Ethane-1,1,1-triyltris(benzene-4,1-diyl)]tris(ethane-1,1,1-triyl)]hexaphenol (DHP, purchased from Accela Chembio Inc., USA) were dissolved in a mixture solvent of n-butyl acetate (nBA) and methyl isobutyl ketone (MIBK) in a volume ratio of about 1:1 to prepare a resist composition solution with a concentration of about 0.8 wt/vol %. The weight ratio of DSBTOC and DHP in the resist composition solution was about 1:0.1.

A solution in which HMDS was dissolved in PGMEA (about 20 wt %) was applied on a silicon substrate at about 3000 rpm for about 30 seconds by spin coating, and the substrate was heated at about 110° C. for about 1 minute. On the substrate treated with HMDS, the resist composition solution was applied at about 2000 rpm for about 60 seconds by spin coating and heated at about 80° C. for about 1 minute to form a resist thin film (thickness of about 21 nm). The resist thin film was irradiated with EUV using a MET5 exposure device owned by Lawrence Berkeley National Laboratory. Then, a developing process was performed on the resist thin film using a mixture solution of a standard aqueous solution of about 2.38% TMAH and DI water (the volume ratio of the standard aqueous solution of about 2.38% TMAH and DI water was about 15:1) for about 1 minute, and washing was performed using DI water for about 15 seconds to form a positive tone resist pattern.

FIG. 15 illustrates scanning electron microscopic images of positive tone resist patterns formed by an extreme ultraviolet lithography process according to Experimental Example 9.

Referring to FIG. 15, extreme ultraviolet of about 70 mJ/cm² was irradiated onto the resist thin film (weight ratio of DSBTOC and DHP=about 1:0.1) formed according to Experimental Example 9, and a developing process was performed using a basic developing solution (TMAH). As a result, a positive tone resist pattern with a line width (CD) of about 18.4 nm (LER/LWR of about 4.84/7.36 nm) was formed. Extreme ultraviolet of about 77 mJ/cm² was irradiated onto the resist thin film (weight ratio of DSBTOC and DHP=about 1:0.1) formed according to Experimental Example 9, and a developing process was performed using a basic developing solution (TMAH). As a result, a positive tone resist pattern with a line width (CD) of about 15.6 nm (LER/LWR of about 4.47/6.69 nm) was formed. After irradiating the resist thin film (weight ratio of DSBTOC and DHP=about 1:0.1) formed according to Experimental Example 9 with extreme ultraviolet of about 91 mJ/cm², a developing process was performed using a basic developing solution (TMAH). As a result, a positive tone resist pattern with a line width (CD) of about 12.6 nm (LER/LWR of about 5.11/7.73 nm) was formed.

In order to demonstrate the Lewis acid-base interaction between the tin-oxo nanocluster and the compound (polymer or organic single molecule) having Lewis basicity in the resist composition according to the inventive concept, an experiment was performed to measure the dissolution rate in a developing solution without performing an exposure process (hereinafter, a solubility (or dark loss) measurement experiment under non-exposure conditions) for the tin-oxo nanocluster, a mixture of the tin-oxo nanocluster and the compound having Lewis basicity, and the compound having Lewis basicity.

### [Experimental Example 10] Dark Loss Measurement Experiment for DSBTOC, Mixture of DSBTOC and P(HOST-MMA), and P(HOST-MMA)

1) DSBTOC was dissolved in a mixture solvent of n-butyl acetate (nBA) and methyl isobutyl ketone (MIBK) (volume ratio of nBA:MIBK=about 1:1) to prepare a composition of about 2.5-3.0 wt/vol %.

2) DSBTOC and a P(HOST-MMA) copolymer were dissolved in a mixture solvent of n-butyl acetate (nBA) and propylene glycol monomethyl ether acetate (PGMEA) (volume ratio of nBA:PGMEA=about 1:4) to prepare a composition of about 2.5-3.0 wt/vol %. The weight ratio between DSBTOC and the P(HOST-MMA) copolymer in the composition was about 1:0.5.

3) DSBTOC and a P(HOST-MMA) copolymer were dissolved in a mixture solvent of n-butyl acetate (nBA) and methyl isobutyl ketone (MIBK) (volume ratio of nBA:MIBK=about 1:1) to prepare a composition of about 2.5-3.0 wt/vol %. The weight ratio between DSBTOC and the P(HOST-MMA) copolymer in the composition was about 1:0.25.

4) DSBTOC and a P(HOST-MMA) copolymer were dissolved in a mixture solvent of n-butyl acetate (nBA) and methyl isobutyl ketone (MIBK) (volume ratio of nBA:MIBK=about 1:1) to prepare a composition of about 2.5-3.0 wt/vol %. The weight ratio between DSBTOC and the P(HOST-MMA) copolymer in the composition was about 1:0.1.

5) A P(HOST-MMA) copolymer was dissolved in a mixture solvent of n-butyl acetate (nBA) and propylene glycol monomethyl ether (PGME) (volume ratio of nBA:PGME=about 1:1) to prepare a composition of about 2.5-3.0 wt/vol %.

Each of the compositions prepared in 1) to 5) was applied on a silicon substrate at about 2000 rpm for about 60 seconds by spin coating and heated at about 80° C. for about 1 minute to form a thin film (thickness of about 90-130 nm). The thin film was immersed in a developing solution obtained by mixing a standard aqueous solution of 2.38% TMAH and DI water (volume ratio of standard aqueous solution of 2.38% TMAH and DI water=about 1:1) for about 1 minute, 3 minutes and 5 minutes, and thickness change was confirmed using a surface profiler.

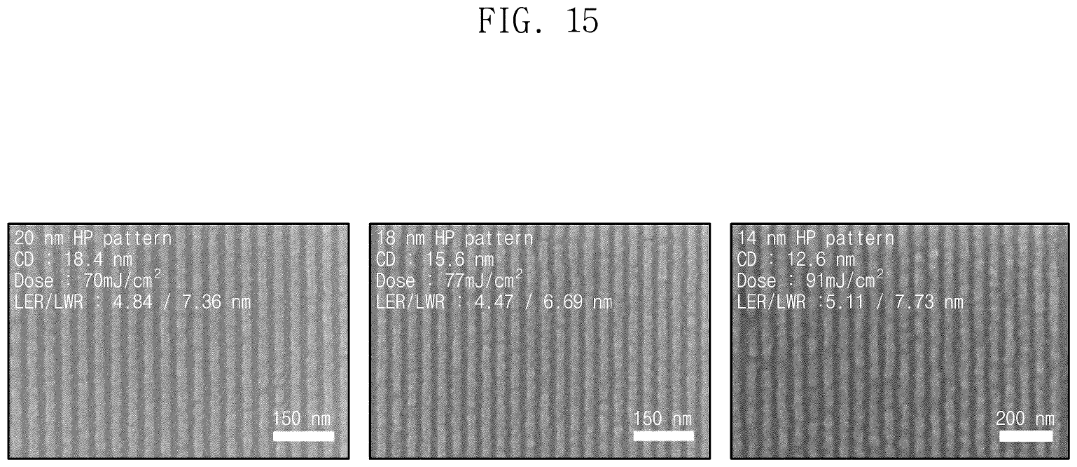

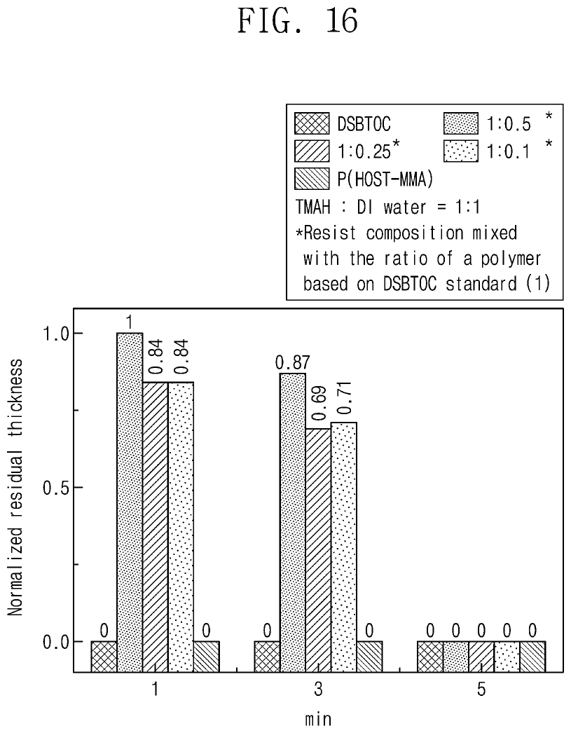

FIG. 16 is a graph showing measurement results of solubility (dark loss) under non-exposure conditions for DSBTOC, a mixture of DSBTOC and P(HOST-MMA), and P(HOST-MMA) according to Experimental Example 10.

Referring to FIG. 16, it was confirmed that the DSBTOC thin film and P(HOST-MMA) thin film were both dissolved within about 1 minute after being immersed in the basic developing solution (TMAH), but the thin film of the mixture of DSBTOC and P(HOST-MMA) was slowly dissolved up to about 3 minutes after being immersed in the basic developing solution (TMAH), and then dissolved.

### [Experimental Example 11] Dark Loss Measurement Experiment for DSBTOC, Mixture of DSBTOC and DHP, and DHP

1) DSBTOC was dissolved in a mixture solvent of n-butyl acetate (nBA) and methyl isobutyl ketone (MIBK) (volume ratio of nBA:MIBK=about 1:1) to prepare a composition of about 2.5-3.0 wt/vol %.

2) DSBTOC and DHP were dissolved in a mixture solvent of n-butyl acetate (nBA) and methyl isobutyl ketone (MIBK) (volume ratio of nBA:MIBK=about 1:1) to prepare a composition of about 2.5-3.0 wt/vol %. The weight ratio between DSBTOC and DHP in the composition was about 1:0.1.

3) DHP was dissolved in 2-methyltetrahydrofuran (2-MeTHF) to prepare a composition of about 2.5-3.0 wt/vol %.

Each of the compositions prepared in 1) to 3) was applied on a silicon substrate at about 2000 rpm for about 60 seconds and heated at about 80° C. for about 1 minute to form a thin film (thickness of about 90-150 nm). The thin film was immersed in a developing solution obtained by mixing a standard aqueous solution of 2.38% TMAH and DI water (volume ratio of standard aqueous solution of 2.38% TMAH and DI water=about 1:2) for about 1 minute, 3 minutes and 5 minutes, and thickness change was confirmed using a surface profiler.

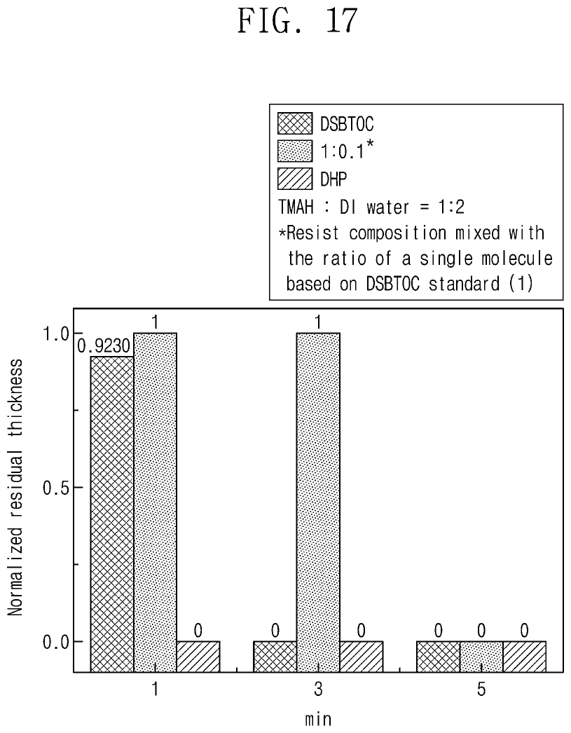

FIG. 17 is a graph showing measurement results of solubility (dark loss) under non-exposure conditions for DSBTOC, a mixture of DSBTOC and DHP, and DHP according to Experimental Example 11.

Referring to FIG. 17, the DHP thin film was dissolved within about 1 minute after being immersed in the basic developing solution (TMAH), and the DSBTOC thin film was dissolved within about 3 minutes after being immersed in the basic developing solution (TMAH). However the thin film of the mixture of DSBTOC and DHP maintained the thickness thereof up to about 3 minutes after being immersed in the basic developing solution (TMAH), and then dissolved.

Through Experimental Examples 10 and 11, it was confirmed that there is Lewis acid-base interaction between the tin-oxo nanocluster (for example, DSBTOC) and the compound having Lewis basicity (for example, P(HOST-MMA) copolymer or DHP single molecule).

The resist composition according to the inventive concept may be a mixture composition including the tin-oxo nanocluster represented by Formula 1, and the compound having Lewis basicity. As confirmed through Experimental Examples 10 and 11, the Lewis acid-based interaction may occur between the tin-oxo nanocluster and the compound having Lewis basicity. Accordingly, the solubility of the resist composition in the basic developing solution may be controlled to a required degree, and as a result, the dissolution contrast between the exposed area and the unexposed area of the photoresist layer formed using the resist composition may increase.

A method for manufacturing a semiconductor device using the resist composition according to embodiments of the inventive concept will be explained.

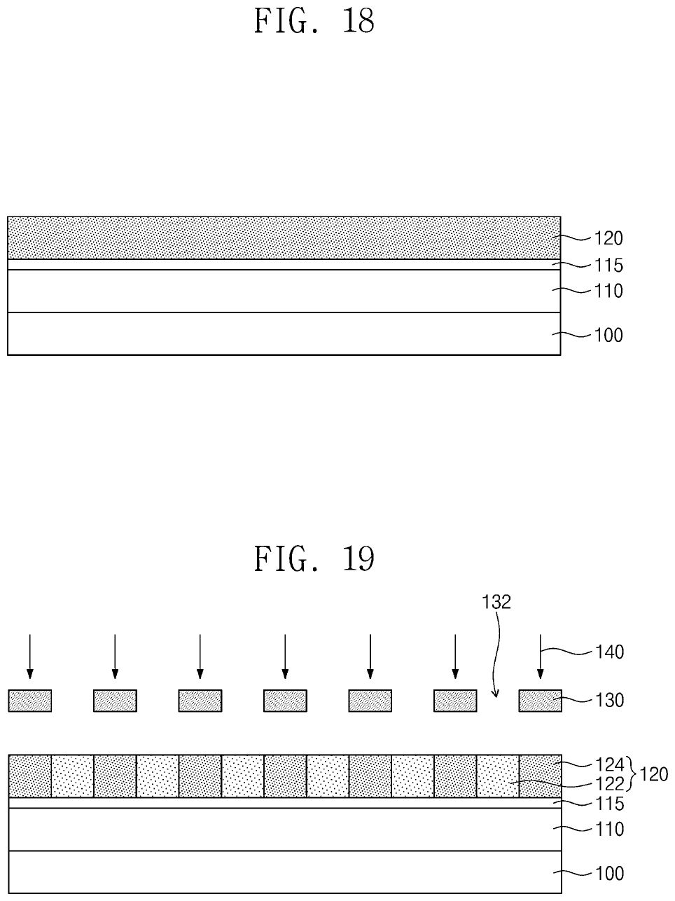

FIGS. 18 to 21 are cross-sectional views showing a method for manufacturing a semiconductor device using the resist composition according to embodiments of the inventive concept.

Referring to FIG. 18, an etching target layer 110 may be formed on a substrate 100, and on the etching target layer 110, an underlayer 115 and a photoresist layer 120 may be formed in order. The substrate 100 may be a semiconductor substrate, for example, a silicon substrate, a germanium substrate or a silicon/germanium substrate. In another embodiment, the substrate 100 may be a metal substrate such as Cr and Ta. The etching target layer 110 may be formed using any one selected from a semiconductor material, a conductive material and an insulating material, or a combination thereof. The etching target layer 110 may be formed as a single layer, or may include multiple layers stacked on the substrate 100.

The underlayer 115 may be formed between the etching target layer 110 and the photoresist layer 120 and may easily fix the photoresist layer 120 on the etching target layer 110. The underlayer 115 may include, for example, hexamethyldisilazane (HMDS), a silane compound containing a vinyl group (for example, vinyl disilazane, vinyl chlorosilane, vinyl oxysilane or the like), a polymer containing a vinyl group, or an organometal oxide. According to some embodiments, the underlayer 115 may be omitted.

The photoresist layer 120 may include the resist composition according to embodiments of the inventive concept. The resist composition may be a mixture composition including an alkylated tin-oxo nanocluster and a compound having Lewis basicity. The alkylated tin-oxo nanocluster may include a core structure including tin oxide, and an alkyl group of 1 to 20 carbon atoms, combined with the tin element of the core structure. The alkylated tin-oxo nanocluster may further include a counter anion ionic bonded with the core structure. The alkylated tin-oxo nanocluster may be represented by Formula 1. The compound having Lewis basicity may include a polymer or an organic single molecule, having a functional group that functions as a Lewis base. The functional group that functions as a Lewis base may be a functional group having lone pair electrons, such as a hydroxyl group, a phenol group, a thiol group, an amine group, a carboxylic acid group, an ester group, a carbonyl group, an amide group, a carbamate group, an urea group, a sulfoxy group, a sulfonyl group, a sulfone ester group, a cyanide group, and an isocyanide group. The compound having Lewis basicity may include any one of a polymer including a repeating unit represented by Formula 5, a polymer including a copolymer represented by Formula 6, or an organic single molecule represented by Formula 7, Formula 8, Formula 9 or Formula 10.

The formation of the photoresist layer 120 may include applying the resist composition on the underlayer 115 (or the etching target layer 110). The applying of the resist composition on the underlayer 115 (or the etching target layer 110) may be performed by, for example, a spin coating method. The formation of the photoresist layer 120 may further include performing heat treatment (for example, soft baking process) on the applied resist composition.

Referring to FIG. 19, an exposing process may be performed on the photoresist layer 120. The exposing process may include irradiating light 140 onto the photoresist layer 120. In an embodiment, the exposing process may include aligning a photomask 130 on the photoresist layer 120 and irradiating the light 140 onto the photoresist layer 120 through the photomask 130. The light 140 may be, for example, extreme ultraviolet. In another embodiment, the exposing process may include irradiating and scanning light 140 onto the photoresist layer 120 using an e-beam lithography apparatus. The light 140 may be, for example, e-beam. The photoresist layer 120 may include a first part 122 exposed to the light 140 and a second part 124 unexposed to the light 140. In an embodiment, the light 140 may be irradiated onto the first part 122 through an opening part 132 of the photomask 130 and may be blocked by the photomask 130 and not irradiated onto the second part 124.

In the first part 122 (for example, exposed area) of the photoresist layer 120, an organic ligand (R) may be separated from the tin-oxo nanocluster represented by Formula 1 by the photons of the light 140, and accordingly, the tin-oxo nanocluster may have strong Lewis acidity. The compound having Lewis basicity may have the functional group that functions as a Lewis base, and the functional group that functions as a Lewis base may be bonded to a tin atom that has lost the organic ligand (R) via acid-base interaction. Accordingly, the first part 122 (for example, exposed area) of the photoresist layer 120 may have a structure in which the organic ligand (R) of the tin-oxo nanocluster represented by Formula 1 is substituted with the functional group that functions as a Lewis base. The second part 124 (for example, unexposed area) of the photoresist layer 120 may include a mixture of the tin-oxo nanocluster represented by Formula 1 and the compound having Lewis basicity. Since the organic ligand (R) of the tin-oxo nanocluster represented by Formula 1 is substituted with the functional group that functions as a Lewis base in the first part 122 (for example, exposed area) of the photoresist layer 120, the solubility of the first part 122 (for example, exposed area) of the photoresist layer with respect to a basic developing solution may be controlled, and the dissolution contrast between the first part 122 (for example, exposed area) and the second part 124 (for example, unexposed area) of the photoresist layer 120 may increase.

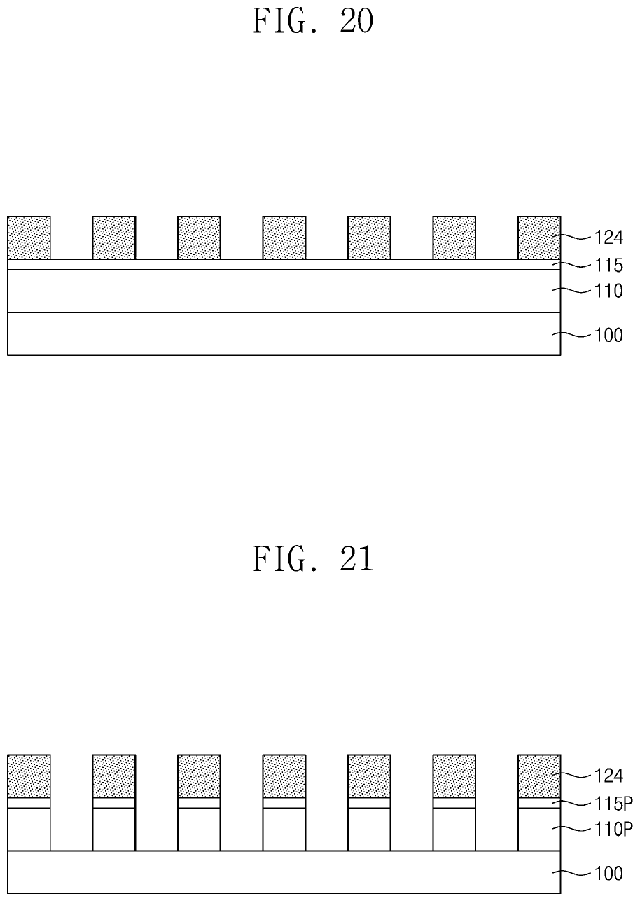

Referring to FIG. 20, after the exposing process, the photomask 130 may be removed. A developing process may be performed on the exposed photoresist layer 120. The developing process may include removing the first part 122 of the photoresist layer 120 using a basic developing solution. The basic developing solution may include, for example, tetramethylammonium hydroxide (TMAH). By the developing process, the first part 122 of the photoresist layer 120 may be selectively removed. The second part 124 of the photoresist layer 120 may be referred to as a photoresist pattern, and the photoresist pattern 124 may be a positive tone pattern.

Referring to FIG. 21, the underlayer 115 and the etching target layer 110 may be etched using the photoresist pattern 124 as an etching mask. The etching of the underlayer 115 and the etching target layer 110 may include, for example, a wet or a dry etching process. The underlayer 115 and etching target layer 110 may be etched to form an underlayer pattern 115P and a lower pattern 110P, respectively. After forming the lower pattern 110P, the photoresist pattern 124 may be removed. The lower pattern 110P may be a semiconductor pattern, a conductive pattern or an insulating pattern in a semiconductor device.

According to embodiments of the inventive concept, the resist composition may be a non-chemically amplified positive tone resist composition. Since the resist composition includes the tin-oxo nanocluster, the resolution and sensitivity of the photoresist layer 120 formed using the resist composition may be improved, and the etching resistance of the photoresist layer 120 may be improved. Since the resist composition further includes the composition having Lewis basicity, after irradiating the light 140, the resist composition may have solubility to a required degree with respect to the basic developing solution. Accordingly, the exposed area 122 of the photoresist layer 120 formed using the resist composition may be removed by the basic developing solution, and the dissolution contrast between the exposed area 122 and the unexposed area 124 of the photoresist layer 120 may increase.

A multilayer structure formed using the resist composition according to the embodiments of the inventive concept will be explained.

Referring to FIG. 18 again, a multilayer structure may include the etching target layer 110 on the substrate 100, and the photoresist layer 120 on the etching target layer 110. According to some embodiments, the underlayer 115 may be disposed between the etching target layer 110 and the photoresist layer 120.

The photoresist layer 120 may include the resist composition according to embodiments of the inventive concept. The resist composition may be a mixture composition including the alkylated tin-oxo nanocluster and the compound having Lewis basicity. The alkylated tin-oxo nanocluster may include a core structure including tin oxide, and an alkyl group of 1 to 20 carbon atoms, combined with the tin element of the core structure. The alkylated tin-oxo nanocluster may further include a counter anion ionic bonded with the core structure. The alkylated tin-oxo nanocluster may be represented by Formula 1. The compound having Lewis basicity may include a polymer or an organic single molecule, having a functional group that functions as a Lewis base. The functional group that functions as a Lewis base may be a functional group having lone pair electrons, such as a hydroxyl group, a phenol group, a thiol group, an amine group, a carboxylic acid group, an ester group, a carbonyl group, an amide group, a carbamate group, an urea group, a sulfoxy group, a sulfonyl group, a sulfone ester group, a cyanide group, and an isocyanide group. The compound having Lewis basicity may include any one of a polymer including a repeating unit represented by Formula 5, a polymer including a copolymer represented by Formula 6, or an organic single molecule represented by Formula 7, Formula 8, Formula 9 or Formula 10.

Referring to FIG. 19 again, according to some embodiments, the photoresist layer 120 may include the first part 122 exposed to the light 140, and the second part 124 unexposed to the light 140. The first part 122 (for example, exposed area) of the photoresist layer 120 may have a structure in which the organic ligand (R) of the tin-oxo nanocluster represented by Formula 1 is substituted with the functional group that functions as a Lewis base. The second part 124 (for example, unexposed area) of the photoresist layer 120 may include a mixture including the tin-oxo nanocluster represented by Formula 1, and the compound having Lewis basicity.

According to the inventive concept, a resist composition may be a non-chemically amplified positive tone resist composition. Since the resist composition includes an alkylated tin-oxo nanocluster, a photoresist layer formed using the resist composition may have high resolution and sensitivity for an e-beam and extreme ultraviolet lithography process, and the etching resistance of the photoresist layer may be improved. Since the resist composition further includes a compound having Lewis basicity, the solubility of the resist composition in a basic developing solution in the exposed area of the photoresist layer may be controlled, and the dissolution contrast between the exposed area and the unexposed area of the photoresist layer may be increased.

Accordingly, a metal oxide-based positive tone resist composition, which has high resolution and sensitivity with respect to an e-beam or extreme ultraviolet lithography process and increased etching resistance may be provided.

Although the embodiments of the present invention have been described, it is understood that the present invention should not be limited to the embodiments, but various changes and modifications can be made by one ordinary skilled in the art within the spirit and scope of the present invention as hereinafter claimed.

What is claimed is:

1. A resist composition comprising:
an alkylated tin-oxo nanocluster, wherein the alkylated tin-oxo nanocluster includes a core structure including tin oxide, and an alkyl group of 1 to 20 carbon atoms, combined with the tin element of the core structure; and
a compound having Lewis basicity,
wherein the compound comprises a polymer or an organic single molecule, the compound having a functional group that functions as a Lewis base, and
wherein the functional group is a functional group containing lone pair electrons.

2. The resist composition of claim 1, wherein the alkylated tin-oxo nanocluster is represented by Formula 1:
[(R—Sn)₁₂O₁₄(OH)₆]²⁺[Rx⁻]₂ [Formula 1]
wherein R is the alkyl group of 1 to 20 carbon atoms, and Rx⁻ is a counter anion and is a sulfonate anion or a carboxylate anion.

3. The resist composition of claim 1, wherein the functional group is any one of a hydroxyl group, a phenol group, a thiol group, an amine group, a carboxylic acid group, an ester group, a carbonyl group, an amide group, a carbamate group, an urea group, a sulfoxy group, a sulfonyl group, a sulfone ester group, a cyanide group, or an isocyanide group.

4. The resist composition of claim 1, wherein the compound comprises a polymer comprising a repeating unit represented by Formula 5: 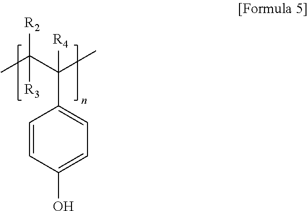
wherein R₂, R₃ and R₄ are each independently hydrogen, deuterium or an alkyl group of 1 to 10 carbon atoms, and n is an integer of 1 to 1000.

5. The resist composition of claim 1, wherein the compound comprises a copolymer represented by Formula 6: 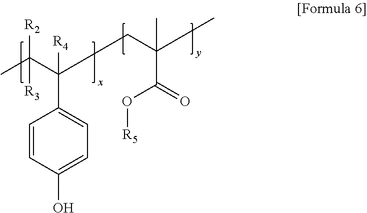
wherein R₂, R₃ and R₄ are each independently hydrogen, deuterium or an alkyl group of 1 to 10 carbon atoms, R₅ is hydrogen, deuterium, an alkyl group of 1 to 10 carbon atoms, or a substituted or unsubstituted hydrocarbon ring of 3 to 30 carbon atoms, x is an integer between 1 and 1000, and y is an integer between 1 and 1000.

6. The resist composition of claim 1, wherein the compound comprises an organic single molecule represented by Formula 7, Formula 8, Formula 9 or Formula 10: 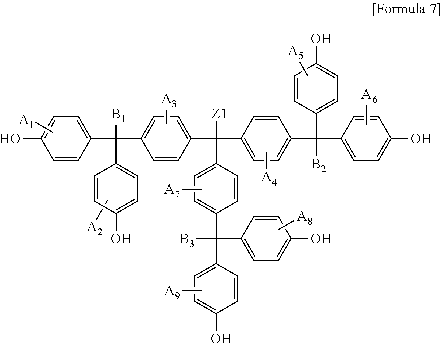
wherein A₁, A₂, A₃, A₄, A₅, A₆, A₇, A₈, and A₉ are each independently hydrogen, deuterium or an alkyl group of 1 to 10 carbon atoms, B₁, B₂, and B₃ are each independently hydrogen, deuterium or an alkyl group of 1 to 10 carbon atoms, and Z1 is hydrogen, deuterium, an alkyl group of 1 to 10 carbon atoms, or a substituted or unsubstituted hydrocarbon ring of 3 to 30 carbon atoms, 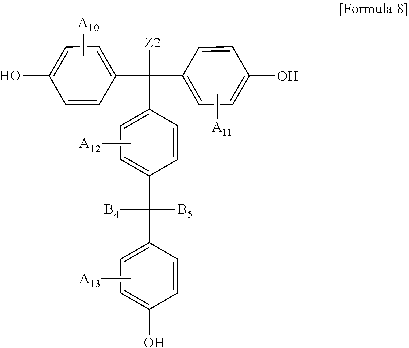
wherein A₁₀, A₁₁, A₁₂ and A₁₃ are each independently hydrogen, deuterium or an alkyl group of 1 to 10 carbon atoms, B₄ and B₅ are each independently hydrogen, deuterium or an alkyl group of 1 to 10 carbon atoms, and Z2 is hydrogen, deuterium, an alkyl group of 1 to 10 carbon atoms, or a substituted or unsubstituted hydrocarbon ring of 3 to 30 carbon atoms, 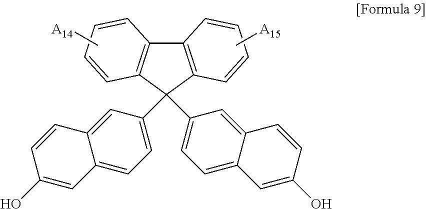
wherein A₁₄ and A₁₅ are each independently hydrogen, deuterium, an alkyl group of 1 to 10 carbon atoms, or a substituted or unsubstituted hydrocarbon ring of 3 to 30 carbon atoms, and 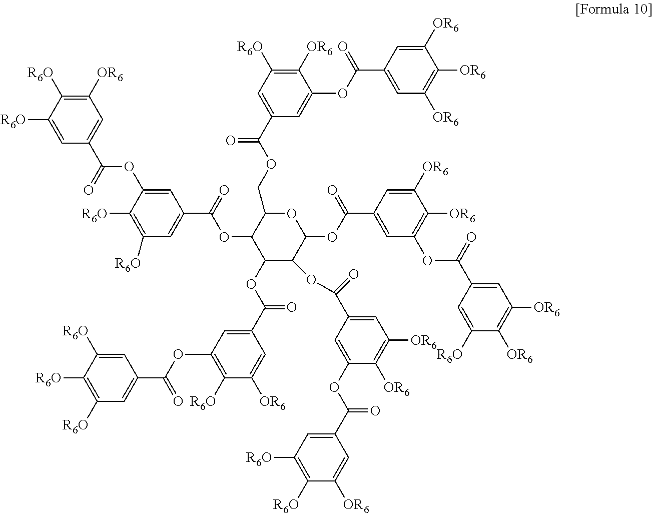
wherein R₆ is represented by the following Formula 11: 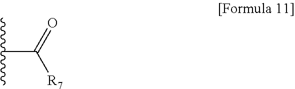
wherein R₇ is hydrogen, deuterium, an alkyl group of 1 to 10 carbon atoms, or a substituted or unsubstituted hydrocarbon ring of 3 to 30 carbon atoms.

7. A method for manufacturing a semiconductor device, the method comprising:
forming an etching target layer on a substrate;
forming a photoresist layer on the etching target layer;
performing an exposing process on the photoresist layer; and
performing a developing process to selectively remove an exposed area of the photoresist layer, wherein
the photoresist layer comprises:
an alkylated tin-oxo nanocluster, wherein the alkylated tin-oxo nanocluster includes a core structure including tin oxide, and an alkyl group of 1 to 20 carbon atoms, combined with the tin element of the core structure; and
a compound having Lewis basicity,
wherein the compound comprises a polymer or an organic single molecule, the compound having a functional group that functions as a Lewis base, and
wherein the functional group is a functional group containing lone pair electrons.

8. The method of claim 7, wherein the alkylated tin-oxo nanocluster is represented by Formula 1:
[(R—Sn)₁₂O₁₄(OH)₆]²⁺[Rx⁻]₂ [Formula 1]
wherein R is the alkyl group of 1 to 20 carbon atoms, and Rx⁻ is a counter anion and is a sulfonate anion or a carboxylate anion.

9. The method of claim 7, wherein the functional group is any one of a hydroxyl group, a phenol group, a thiol group, an amine group, a carboxylic acid group, an ester group, a carbonyl group, an amide group, a carbamate group, an urea group, a sulfoxy group, a sulfonyl group, a sulfone ester group, a cyanide group, or an isocyanide group.

10. The method of claim 7, wherein
the photoresist layer comprises an exposed area exposed through the exposing process, and an unexposed area unexposed through the exposing process, and
the exposed area of the photoresist layer has a structure in which the alkyl group of the tin-oxo nanocluster is substituted with the functional group of the compound.

11. The method of claim 10, wherein the unexposed area of the photoresist layer comprises a mixture of the tin-oxo nanocluster and the compound.

12. The method of claim 7, wherein the exposing process is performed using e-beam or extreme ultraviolet.

13. The method of claim 7, wherein the developing process is performed using a basic developing solution.

14. The method of claim 7, wherein the compound comprises the polymer, the polymer having a phenol group.

15. The method of claim 14, wherein the polymer comprises a repeating unit represented by Formula 5: 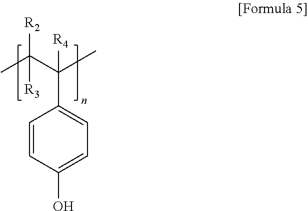
wherein R₂, R₃ and R₄ are each independently hydrogen, deuterium or an alkyl group of 1 to 10 carbon atoms, and n is an integer of 1 to 1000.

16. The method of claim 14, wherein the compound comprises a copolymer represented by Formula 6: 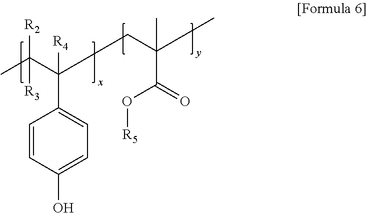
wherein R₂, R₃ and R₄ are each independently hydrogen, deuterium or an alkyl group of 1 to 10 carbon atoms, R₅ is hydrogen, deuterium, an alkyl group of 1 to 10 carbon atoms, or a substituted or unsubstituted hydrocarbon ring of 3 to 30 carbon atoms, x is an integer between 1 and 1000, and y is an integer between 1 and 1000.

17. The method of claim 7, wherein the compound comprises the organic single molecule, the organic single molecule having a phenol group.

18. The method of claim 17, wherein the compound comprises the organic single molecule, wherein the organic single molecule is represented by Formula 7, Formula 8 or Formula 9: 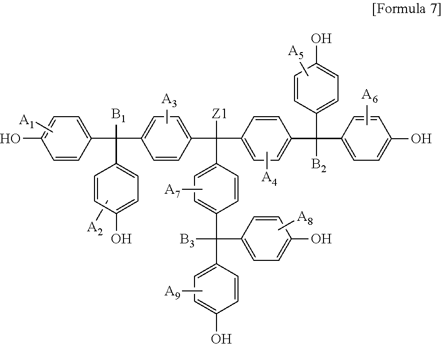
wherein A₁, A₂, A₃, A₄, A₅, A₆, A₇, A₈, and A₉ are each independently hydrogen, deuterium or an alkyl group of 1 to 10 carbon atoms, B₁, B₂, and B₃ are each independently hydrogen, deuterium or an alkyl group of 1 to 10 carbon atoms, and Z1 is hydrogen, deuterium, an alkyl group of 1 to 10 carbon atoms, or a substituted or unsubstituted hydrocarbon ring of 3 to 30 carbon atoms, 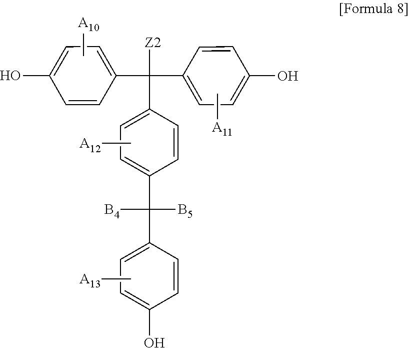
wherein A₁₀, A₁₁, A₁₂ and A₁₃ are each independently hydrogen, deuterium or an alkyl group of 1 to 10 carbon atoms, B₄ and B₅ are each independently hydrogen, deuterium or an alkyl group of 1 to 10 carbon atoms, and Z2 is hydrogen, deuterium, an alkyl group of 1 to 10 carbon atoms, or a substituted or unsubstituted hydrocarbon ring of 3 to 30 carbon atoms, and 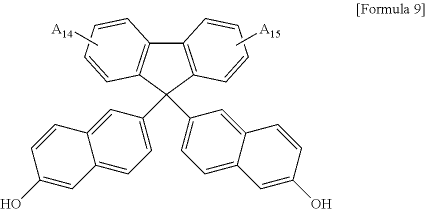
wherein A₁₄ and A₁₅ are each independently hydrogen, deuterium, an alkyl group of 1 to 10 carbon atoms, or a substituted or unsubstituted hydrocarbon ring of 3 to 30 carbon atoms.

19. The method of claim 7, wherein the compound comprises an organic single molecule, the organic single molecule having an ester group.

20. The method of claim 19, wherein the compound comprises an organic single molecule represented by t Formula 10: 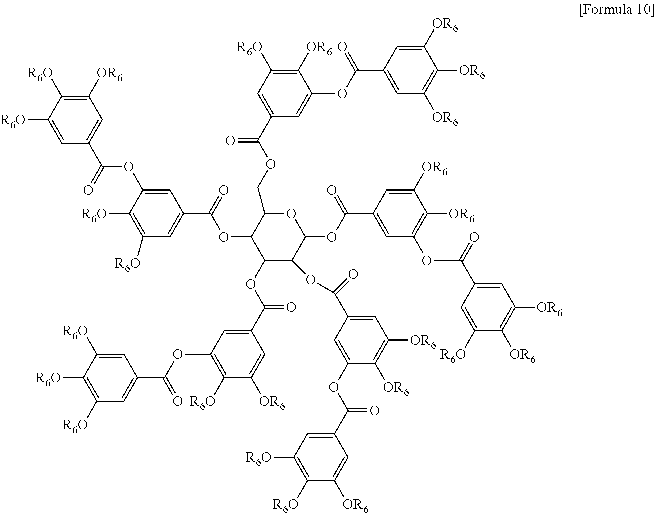
wherein R₆ is represented by the following Formula 11: 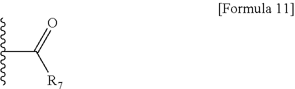
wherein R₇ is hydrogen, deuterium, an alkyl group of 1 to 10 carbon atoms, or a substituted or unsubstituted hydrocarbon ring of 3 to 30 carbon atoms.
